(19) United States
(12) Patent Application Publication
(10) Pub. No.: US 2023/0025136 A1
(43) Pub. Date: Jan. 26, 2023

(54) AIR-CONDITIONING APPARATUS

(71) Applicant: Mitsubishi Electric Corporation, Tokyo (JP)

(72) Inventors: Naoki YAMADA, Tokyo (JP); Kenta YUASA, Tokyo (JP)

(21) Appl. No.: 17/786,769

(22) PCT Filed: Feb. 10, 2021
(86) PCT No.: PCT/JP2021/004887

§ 371 Date: Jun. 17, 2022

(30) Foreign Application Priority Data
Feb. 21, 2020 (JP) PCT/JP2020/006956

(51) Int. Cl. F24F 11/30; F25B 49/02; F24F 11/88; F24F 11/89; F25B 41/31

(52) U.S. Cl. CPC F24F 11/30; F25B 49/022; F24F 11/88; F24F 11/89; F25B 41/31

(57) ABSTRACT

An air-conditioning apparatus includes a bypass pipe through which part of refrigerant discharged from a discharge port of a compressor flows. Heating components provided on a substrate of the controller include a first heating component and a second heating component that generates a smaller amount of heat than the first heating component. The first heating component is provided such that a longitudinal direction of the first heating component is parallel to a flow direction of the refrigerant in the bypass pipe, the longitudinal direction being a direction in which long sides of the first heating component extend. The second heating component is provided such that a widthwise direction of the second heating component is parallel to the flow direction of the refrigerant in the bypass pipe, the widthwise direction being a direction in which short sides of the second heating component extend.

### CROSS REFERENCE TO RELATED APPLICATION

This application is a U.S. national stage application of International Patent Application No. PCT/JP2021/004887 filed on Feb. 10, 2021, which claims priority to International Patent Application No. PCT/JP2020/006956 filed on Feb. 21, 2020, the disclosure of which is incorporated herein by reference.

### TECHNICAL FIELD

The present disclosure relates to an air-conditioning apparatus that includes a controller in which heating components are mounted.

### BACKGROUND

In existing air-conditioning apparatuses including an inverter compressor, an inverter circuit that controls the rotation speed of a compressor is provided. In general, an inverter circuit uses a heating component such as a power element that generates high heat.

For example, Patent Literature 1 describes an air-conditioning apparatus that includes a cooling member that cools such a heating component as described above.

In the air-conditioning apparatus described in Patent Literature 1, the cooling member includes a refrigerant jacket made of metal having a high thermal conductivity, and a refrigerant pipe embedded in the refrigerant jacket. A sub refrigerant circuit that branches off from a main refrigerant circuit is connected to a refrigerant pipe of the cooling member. Refrigerant discharged from a compressor flows mainly through the main refrigerant circuit. However, after the refrigerant passes through a condenser, part of the refrigerant flows through the sub refrigerant circuit via a second expansion valve. The refrigerant jacket is in intimate contact with a surface of the heating component. Refrigerant from the sub refrigerant circuit flows through the refrigerant pipe of the cooling member, thereby cooling the heating component.

In the existing air-conditioning apparatus described in Patent Literature 1, a control module determines in advance a target cooling temperature of the heating component. When the temperature of the refrigerant jacket is higher than the target cooling temperature, in order to promote cooling of the heating component, the control module opens a second expansion valve to increase the flow rate of refrigerant that flows through the refrigerant pipe of the cooling member. By contrast, when the temperature of the refrigerant jacket is lower than the target cooling temperature, the control module closes the second expansion valve to reduce the flow rate of refrigerant that flows through the refrigerant pipe of the cooling member.

### PATENT LITERATURE

Patent Literature 1: International Publication No. 2019/069470

In the existing air-conditioning apparatus described in Patent Literature 1, a discharge-gas branch refrigerant circuit is further provided to prevent condensation. The discharge-gas branch refrigerant circuit is provided parallel to the main refrigerant circuit, in a region from a region between the compressor and a four-way valve to a region between the second expansion valve and the cooling member. In the discharge gas branch refrigerant circuit, a solenoid valve is provided. When the temperature of the cooling member is lower than a condensation temperature, condensation occurs at the heating component and the surroundings thereof. Therefore, in Patent Literature 1, when the temperature of the cooling member is lower than the condensation temperature, the control module opens the solenoid valve. When the solenoid valve is opened, part of high-pressure and high-temperature gas refrigerant discharged from the compressor flows to the sub-refrigerant circuit via the discharge gas branch refrigerant circuit. Thus, it is possible to increase the temperature of the cooling member, which has fallen below the condensation temperature, and thus to prevent occurrence of condensation at the heating component and its surroundings. In such a manner, in Patent Literature 1, the discharge gas branch refrigerant circuit and the solenoid valve are added to control the temperature of refrigerant that flows through the sub refrigerant circuit. Therefore, the configuration of the air-conditioning apparatus is complicated and the cost thereof is increased.

### SUMMARY

The present disclosure is made to solve the above problem, and relates to an air-conditioning apparatus capable of cooling heating components while preventing occurrence of condensation with a simple configuration that does not need the addition of a solenoid valve or other components.

According to an embodiment of the present disclosure, includes:

a refrigerant circuit in which a compressor, a condenser, an expansion valve, and an evaporator are connected by a refrigerant pipe through which refrigerant flows;

a bypass pipe through which part of the refrigerant discharged from a discharge port of the compressor flows; and

a controller configured to control an operation of the compressor,

wherein

both ends of the bypass pipe are connected to respective portions of the refrigerant pipe that are located between the condenser and a suction port of the compressor,

the controller includes
a substrate,
a control module configured to control the operation of the compressor,
a plurality of heating components provided on the substrate, and
a cooling plate that is provided between the bypass pipe and the plurality of heating components and configured to cool the plurality of heating components with the refrigerant flowing through the bypass pipe,

the plurality of heating components include
a first heating component, and
a second heating component configured to generate a smaller amount of heat than the first heating component,

the first heating component and the second heating component are provided in a region of the cooling plate that overlaps with the bypass pipe as the cooling plate is viewed in plan,

each of the first heating component and the second heating component has long sides and short sides as viewed in plan,

the first heating component is provided such that a longitudinal direction of the first heating component is parallel to a flow direction of the refrigerant in the bypass pipe, the longitudinal direction of the first heating component being a direction in which the long sides of the first heating component extends, and

the second heating component is provided such that a widthwise direction of the second heating component is parallel to the flow direction of the refrigerant in the bypass pipe, the widthwise direction of the second heating component being a direction in which the short sides of the second heating component extend.

In the air-conditioning apparatus according to the embodiment of the present disclosure, it is possible to cool heating components while preventing occurrence of condensation with a simple configuration that does not need the addition of a solenoid valve or other components by devising the layout of the heating components.

### BRIEF DESCRIPTION OF DRAWINGS

FIG. 1 is a configuration diagram illustrating a configuration of an air-conditioning apparatus according to Embodiment 1.

FIG. 2 is a plan view illustrating an internal configuration of a controller 5 of the air-conditioning apparatus according to Embodiment 1.

FIG. 3 is a circuit diagram illustrating a configuration of a power converter provided in the controller 5 of the air-conditioning apparatus according to Embodiment 1.

FIG. 4 is a plan view illustrating an internal configuration of the controller 5 of the air-conditioning apparatus according to Embodiment 1.

FIG. 5 is a side view illustrating the internal configuration of the controller 5 of the air-conditioning apparatus according to Embodiment 1.

FIG. 6 is a flowchart indicating a control flow of a control module 10 of the air-conditioning apparatus according to Embodiment 1.

FIG. 7 is a view indicating an example of a temperature change graph for illustrating the flowchart of FIG. 6.

FIG. 8 is a circuit diagram illustrating the configuration of a power converter provided in a controller 5 of an air-conditioning apparatus according to Embodiment 2.

FIG. 9 is a flowchart indicating the control flow of a control module 10 of the air-conditioning apparatus according to Embodiment 2.

FIG. 10 is a view indicating an example of a temperature change graph for illustrating the flowchart of FIG. 9.

FIG. 11 is a plan view illustrating a cooling plate 6 and heating components 4a to 4d in an air-conditioning apparatus according to Embodiment 3.

FIG. 12 is a side view illustrating an internal configuration of a controller 5 of the air-conditioning apparatus according to Embodiment 3.

FIG. 13 is a plan view illustrating the internal configuration of the controller 5 of the air-conditioning apparatus according to Embodiment 3.

FIG. 14 is a configuration diagram illustrating a configuration of a modification of the air-conditioning apparatus according to Embodiment 1.

FIG. 15 is a configuration diagram illustrating a configuration of another modification of the air-conditioning apparatus according to Embodiment 1.

FIG. 16 is a configuration diagram illustrating a configuration of still another modification of the air-conditioning apparatus according to Embodiment 1.

FIG. 17 is a plan view illustrating the case where a “smaller peripheral component 70” is mounted on a substrate 20 as illustrated FIG. 2.

### DETAILED DESCRIPTION

The embodiments of an air-conditioning apparatus according to the present disclosure will be described with reference to the drawings. The present disclosure is not limited to the following Embodiments 1 to 3, and various modifications can be made without departing from the gist of the present disclosure. The present disclosure encompasses all combinations of combinable configurations among configurations that will be described regarding the following embodiments and their modifications. In each of figures, components that are the same as or equivalent to those in a previous figure or previous figures are denoted by the same reference signs, and the same is true of the entire text of the specification. In the figures, relative relationships in size and shape between components may be different from those between actual ones.

### Embodiment 1

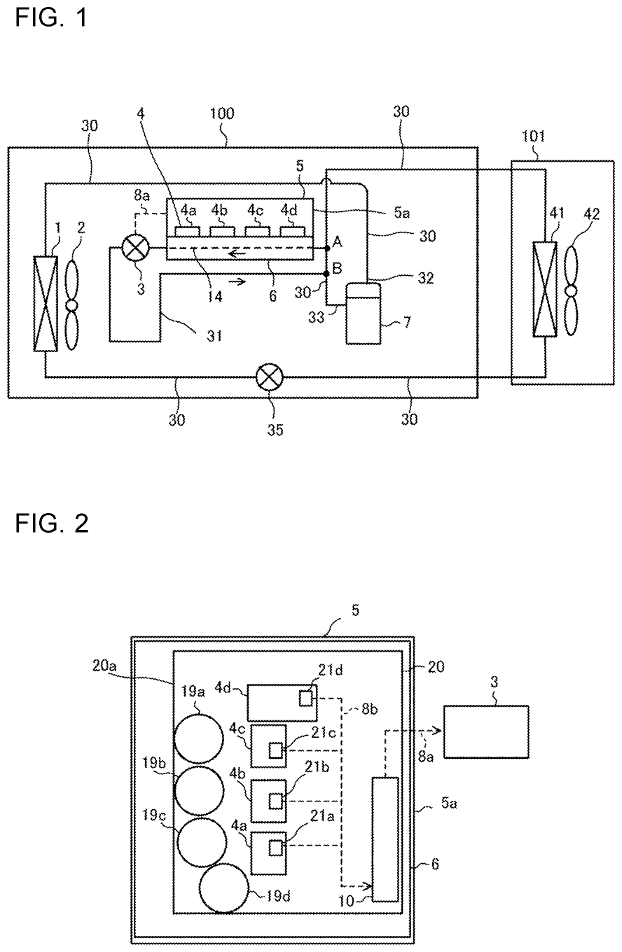

FIG. 1 is a configuration diagram illustrating a configuration of an air-conditioning apparatus according to Embodiment 1. FIG. 1 illustrates a refrigerant circuit diagram in the case where the air-conditioning apparatus is in cooling operation. In FIG. 1, although illustration of a four-way valve is omitted, four-way valves may be provided between a discharge port 32 of a compressor 7 and both a heat exchanger 1 of an outdoor unit 100 and a heat exchanger 41 of an indoor unit 101. In the case where the four-way valve is provided, the air-conditioning apparatus is capable of switching the operation thereof between a cooling operation and a heating operation.

As illustrated in FIG. 1, the air-conditioning apparatus includes the outdoor unit 100 and the indoor unit 101. The outdoor unit 100 and the indoor unit 101 are connected by refrigerant pipe 30.

The indoor unit 101 is installed in an indoor space to be air-conditioned by the air-conditioning apparatus. The indoor unit 101 includes the heat exchanger 41 and an indoor-unit fan 42. The indoor-unit fan 42 sends indoor air to the heat exchanger 41. The heat exchanger 41 includes a heat transfer tube therein and causes heat exchange to be performed between indoor air and refrigerant that flows through the heat transfer tube. The heat exchanger 41 is, for example, a fin and tube heat exchanger. The heat exchanger 41 operates as a load heat exchanger. The indoor-unit fan 42 is, for example, a propeller fan. When the air-conditioning apparatus is in cooling operation, the heat exchanger 41 of the indoor unit 101 operates as an evaporator. By contrast, when the air-conditioning apparatus is heating operation, the heat exchanger 41 of the indoor unit 101 operates as a condenser.

The outdoor unit 100 is installed outside the indoor space. The outdoor unit 100 includes the heat exchanger 1, an outdoor-unit fan 2, the compressor 7, and an expansion valve 35. The outdoor-unit fan 2 sends outside air to the heat exchanger 1. The heat exchanger 1 includes a heat transfer tube therein and causes heat exchange to be performed between outside air and refrigerant that flows through the heat transfer tube. The heat exchanger 1 is, for example, a fin and tube heat exchanger. The heat exchanger 1 operates as a heat source heat exchanger. The outdoor-unit fan 2 is, for example, a propeller fan. When the air-conditioning apparatus is in cooling operation, the heat exchanger 1 of the outdoor unit 100 operates as a condenser. By contrast, when the air-conditioning apparatus is in heating operation, the heat exchanger 1 of the outdoor unit 100 operates as an evaporator.

The compressor 7 compresses low-pressure refrigerant sucked from a suction port 33 to change it into high-pressure refrigerant, and discharges the high-pressure refrigerant from the discharge port 32. The suction port 33 is provided on a suction side of the compressor 7, and the discharge port 32 is provided on a discharge side of the compressor 7. The compressor 7 is, for example, an inverter compressor whose operation frequency is adjustable. In the compressor 7, an operation frequency range is determined in advance. The compressor 7 operates at the operation frequency which is adjusted within the operation frequency range under control by the control module 10 as illustrated in FIG. 2 (described later). As illustrated in FIG. 1, when the air-conditioning apparatus is in cooling operation, the refrigerant discharged from the discharge port 32 of the compressor 7 flows into the heat exchanger 1 of the outdoor unit 100. By contrast, when the air-conditioning apparatus is in heating operation, the refrigerant discharged from the discharge port 32 of the compressor 7 flows into the heat exchanger 41 of the indoor unit 101 via the four-way valve (not illustrated).

The expansion valve 35 is connected between the heat exchanger 1 of the outdoor unit 100 and the heat exchanger 41 of the indoor unit 101. The expansion valve 35 is a valve that decompresses refrigerant. The expansion valve 35 is, for example, an electronic expansion valve whose opening degree can be adjusted under control by the control module 10 as illustrated in FIG. 2 (described later), which is provided in the controller 5.

As illustrated in FIG. 1, the compressor 7, the heat exchanger 1, the expansion valve 35, and the heat exchanger 41 are connected by refrigerant pipes 30, whereby a refrigerant circuit is provided.

As illustrated in FIG. 1, the outdoor unit 100 includes the controller 5. As illustrated in FIG. 1, the controller 5 includes a cooling plate 6 and a plurality of heating components 4 attached to the cooling plate 6. The plurality of heating components 4 includes heating components 4a, 4b, 4c, and 4d. As indicated by a dashed line in FIG. 1, a cooling refrigerant pipe 14 is attached to the cooling plate 6. The cooling refrigerant pipe 14 is part of a bypass pipe 31. The bypass pipe 31 is a refrigerant pipe provided between a connection point A and a connection point B as indicated in FIG. 1. Both the connection point A and the connection point B are located at the refrigerant pipe 30 provided on the suction side of the compressor 7. When the air-conditioning apparatus is in cooling operation, the connection point A and the connection point B are provided between the suction port 33 of the compressor 7 and the heat exchanger 41 of the indoor unit 101, which operates as an evaporator, as illustrated in FIG. 1. One end of the bypass pipe 31 is connected to the refrigerant pipe 30 at the connection point A, and the other end of the bypass pipe 31 is connected to the refrigerant pipe 30 at the connection point B. The connection point B is located closer to the suction port 33 of the compressor 7 than the connection point A. That is, in the flow direction of refrigerant, the connection point A is located on the upstream side, and the connection point B is located on the downstream side.

When the air-conditioning apparatus is in cooling operation, refrigerant that flows out from the heat exchanger 41 of the indoor unit 101 branches into two refrigerant streams at the connection point A. One of the refrigerant streams flows into the refrigerant pipe 30, and the other refrigerant stream flows into the bypass pipe 31. The refrigerant stream that has flowed into the bypass pipe 31 passes through the cooling refrigerant pipe 14. The refrigerant stream that has passed through the cooling refrigerant pipe 14 and the refrigerant stream which is to be sucked into the suction port 33 of the compressor 7 via the refrigerant pipe 30 join each other at the connection point B to combine into single refrigerant. The refrigerant is sucked into the suction port 33 of the compressor 7.

Similarly, when the air-conditioning apparatus is in heating operation, refrigerant that flows out from the heat exchanger 41 of the indoor unit 101 branches into two refrigerant streams at the connection point A. One of the refrigerant streams flows into the refrigerant pipe 30, and the other refrigerant stream flows into the bypass pipe 31. The refrigerant stream that has flowed into the bypass pipe 31 passes through the cooling refrigerant pipe 14. The refrigerant stream that has passed through the cooling refrigerant pipe 14 joins the refrigerant stream, which is to be sucked into the suction port 33 of the compressor 7 via the refrigerant pipe 30, at the connection point B; that is these refrigerant streams combine into single refrigerant. The refrigerant is sucked into the suction port 33 of the compressor 7.

In such a manner, both ends (that is, the connection points A and B) of the bypass pipe 31 are connected to the refrigerant pipe 30 on the low-pressure side between the evaporator (that is, the heat exchanger 1 or the heat exchanger 41) and the suction port 33 of the compressor 7. The operation and configuration of the air-conditioning apparatus according to Embodiment 1 are not limited to those in the above case. Modifications of the air-conditioning apparatus according to the embodiment will be described. FIGS. 14 to 16 are configuration diagrams illustrating configurations of modifications of the air-conditioning apparatus according to Embodiment 1. For example, as illustrated regarding the modifications in FIGS. 14 to 16, the both ends (that is, the connection points A and B) of the bypass pipe 31 may be connected to the refrigerant pipe 30 at any two locations on the low-pressure side between the condenser (that is, the heat exchanger 41 or the heat exchanger 1) and the suction port 33 of the compressor 7.

In the modification as illustrated in FIG. 14, the both ends (that is, the connection points A and B) of the bypass pipe 31 are connected to the heat exchanger 1 that operates as a condenser. Specifically, the both ends of the bypass pipe 31 are connected to respective portions of the heat transfer tube provided in the heat exchanger 1 (condenser). In this case, in the flow direction of refrigerant, the connection point A is located on the upstream side, and the connection point B is located on the downstream side. That is, in the modification as illustrated in FIG. 14, the both ends (that is, the connection points A and B) of the bypass pipe 31 are connected between the upstream side and the downstream side in the condenser.

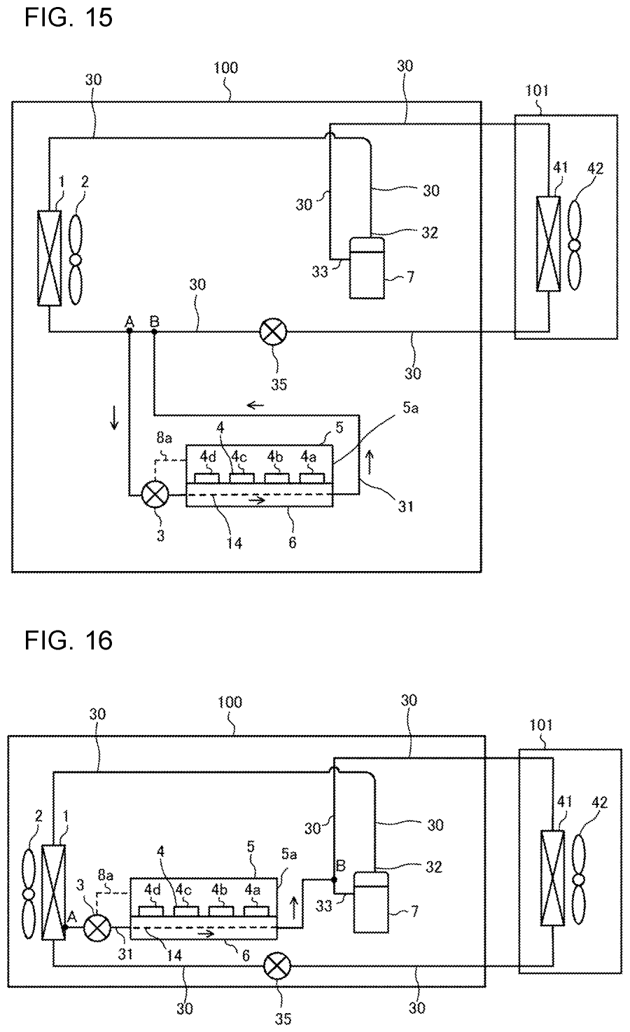

In the modification as illustrated in FIG. 15, the both ends (that is, the connection points A and B) of the bypass pipe 31 are each connected to the refrigerant pipe 30 between the heat exchanger 1 that operates as a condenser and the expansion valve 35. In this case, in the flow direction of refrigerant, the connection point A is located on the upstream side, and the connection point B is located on the downstream side. This configuration is, however, not limiting. The both ends (that is, the connection points A and B) of the bypass pipe 31 may each be connected to the refrigerant pipe 30 between the expansion valve 35 and the heat exchanger 41 that operates as an evaporator.

In the modification as illustrated in FIG. 16, the both ends (that is, the connection points A and B) of the bypass pipe 31 are connected to respective portions of the refrigerant pipe 30 that are located between the heat exchanger 1 that operates as a condenser and the suction port 33 of the compressor 7. In this case, in the flow direction of refrigerant, the connection point A is located on the upstream side, and the connection point B is located on the downstream side. Specifically, one end (that is, the connection point A) of the bypass pipe 31 is connected to the downstream side of the heat exchanger 1 that operates as a condenser. Therefore, refrigerant that is condensed in the heat exchanger 1 to change into single-phase liquid refrigerant flows through the bypass pipe 31. This refrigerant flows via the cooling refrigerant pipe 14 toward the connection point B located close to the suction port 33 of the compressor 7.

As described above, in Embodiment 1, it suffices that the both ends (that is, the connection points A and B) of the bypass pipe 31 are connected to respective portions of the refrigerant pipe 30 that are arbitrarily located on the low-pressure side between the heat exchanger 1 that operates as a condenser and the suction port 33 of the compressor 7. Specifically, it suffices that the both ends of the bypass pipe 31 are provided at locations between the evaporator and the suction port 33 of the compressor 7 (see FIG. 1), or between the upstream side and downstream side of the heat transfer tube in the condenser (see FIG. 14), or between the condenser and the expansion valve 35 (see FIG. 15), or between the expansion valve 35 and the evaporator, or between the condenser and the suction port 33 of the compressor 7 (see FIG. 16), and the above both ends are connected to the refrigerant pipe 30.

As illustrated in FIG. 1, a refrigerant flow control device 3 that adjusts the flow rate of refrigerant is provided at the cooling refrigerant pipe 14. The refrigerant flow control device 3 is, for example, an on-off valve. The state of the refrigerant flow control device 3 is switched between the ON-state (opened state) and the OFF-state (closed state) in response to a control signal 8a from the control module 10 as illustrated in FIG. 2 (described later), which is provided in the controller 5.

As illustrated in FIG. 1, the heating components 4d, 4c, 4b, and 4a are provided in order in the flow direction of refrigerant in the cooling refrigerant pipe 14. The heating component 4d is located on the most upstream side, and the heating component 4a is located on the most downstream side.

FIG. 2 is a plan view illustrating an internal configuration of the controller 5 of the air-conditioning apparatus according to Embodiment 1. As illustrated in FIGS. 1 and 2, the controller 5 has a cuboid housing 5a. FIG. 2 illustrates a configuration of the inside of the housing 5a. The cooling plate 6 having a rectangular shape as viewed in plan is provided in the housing 5a. The cooling plate 6 is formed in the shape of a plate. The cooling plate 6 is made of metal having a high thermal conductivity, such as copper or aluminum. The cooling plate 6 operates as a heatsink. A substrate 20 is provided on an upper surface of the cooling plate 6. The heating components 4a, 4b, 4c, and 4d are attached to an upper surface or a lower surface of the substrate 20. That is, although FIG. 2 illustrates the case where the heating components 4a, 4b, 4c, and 4d are provided on the upper surface of the substrate 20, the heating components 4a, 4b, 4c, and 4d may be provided on the lower surface of the substrate 20 as illustrated in FIG. 5, which will be referred to later. Each of the heating components 4a, 4b, 4c, and 4d has a rectangular or substantially rectangular shape as viewed in plan as in FIG. 2.

Therefore, each of the heating components 4a, 4b, 4c, and 4d has long sides and short sides as viewed in plan. The direction in which the long sides of the heating components 4a, 4b, 4c, and 4d extend will be referred to as “longitudinal direction”, and the direction in which the short sides of the heating components 4a, 4b, 4c, and 4d extend will be referred to as “widthwise direction”. The heating components 4a, 4b, 4c, and 4d are arranged in a line in a direction parallel to a side 20a of the substrate 20 as illustrated in FIG. 2. The side 20a of the substrate 20 is one of the long sides extending in the longitudinal direction of the substrate 20. As illustrated in FIG. 5 (described later), each of the heating components 4a, 4b, 4c, and 4d has a height as viewed side-on. As illustrated in FIG. 2, the control module 10 is mounted on the upper surface of the substrate 20. Other components 19a, 19b, 19c, and 19d are further mounted on the upper surface of the substrate 20. The amount of heat generated by the other components 19a, 19b, 19c, and 19d is smaller than the amount of heat generated by the heating components 4a, 4b, 4c, and 4d.

As illustrated in FIG. 2, temperature detectors 21a, 21b, 21c, and 21d are provided at the heating components 4a, 4b, 4c, and 4d. The temperature detectors 21a, 21b, 21c, and 21d are, for example, internal thermistors that are provided in the heating components 4a, 4b, 4c, and 4d, respectively. Alternatively, the temperature detectors 21a, 21b, 21c, and 21d are, for example, temperature sensors that are provided in the heating components 4a, 4b, 4c, and 4d or on outer surfaces of the heating components 4a, 4b, 4c, and 4d, respectively. To be more specific, the temperature detector 21a detects the temperature of the heating component 4a ; the temperature detector 21b detects the temperature of the heating component 4b ; the temperature detector 21c detects the temperature of the heating component 4c ; and the temperature detector 21d detects the temperature of the heating component 4d. Each of the temperatures detected by the temperature detectors 21a, 21 b, 21c, and 21d is transmitted to the control module 10 as temperature information 8b. The control module 10 produces a control signal 8a, using the temperature information 8b and a specific computation expression stored in a memory in advance. The state of the refrigerant flow control device 3 is switched between the ON-state and the OFF-state in response to the control signal 8a. When the refrigerant flow control device 3 is in the ON-state (opened state), the refrigerant flows through the cooling refrigerant pipe 14. By contrast, when the refrigerant flow control device 3 is in the OFF-state (closed state), the refrigerant does not flow through the cooling refrigerant pipe 14.

As illustrated in FIG. 2, the heating components 4a, 4b, and 4c are provided in a line such that the longitudinal direction of each of the heating components 4a, 4b, and 4c is parallel to the side 20a of the substrate 20 as illustrated in FIG. 2. Therefore, one of the short sides of the heating component 4a and one of the short sides of the heating component 4b are provided to face each other and apart from each other by a certain distance. The other of the short sides of the heating component 4b and one of the short sides of the heating component 4c are provided to face each other and apart from each other by a certain distance. By contrast, as illustrated in FIG. 2, the longitudinal direction of the heating component 4d is perpendicular to the longitudinal direction of the heating components 4a to 4c. The other of the short sides of the heating component 4c and one of the long sides of the heating component 4d are provided to face each other and apart from each other by a certain distance.

In such a manner, the heating components 4a to 4c are arranged in a line and in proximity to each other such that the short sides thereof face each other in the above manner. The heating component 4d is provided adjacent to the first or last one of the heating components 4a to 4c arranged in a line. It should be noted that the first one of the heating components is a heating component located on the most upstream side in the flow direction of refrigerant the cooling refrigerant pipe 14, and the last one of the heating components is a heating component located on the most downstream side in the flow direction of the refrigerant in the cooling refrigerant pipe 14. In an example as illustrated in FIG. 2, of the heating components 4a to 4c, the heating component 4c is the heating component located on the most upstream side, and the heating component 4a is the heating component located on the most downstream side. In the example of FIG. 2, the heating component 4d is provided adjacent to the heating component 4c located on the most upstream side, and apart from the heating component 4c by a certain distance. Therefore, in the example of FIG. 2, of the heating components 4a to 4d, the heating component 4d is the heating component located on the most upstream side. The heating component 4d located on the most upstream side is provided such that the longitudinal direction of the heating component 4d is perpendicular to the longitudinal direction of the other three heating components, and the heating components 4a to 4d are provided in proximity to each other.

Then, the hardware of the control module 10 will be described. The control module 10 includes a storage device (not illustrated). The control module 10 is a processing circuit. The processing circuit is dedicated hardware or a processor. The dedicated hardware is, for example, an application specific integrated circuit (ASIC), a field programmable gate array (FPGA), or other devices. The processor executes a program stored in a memory. The storage device provided in the control module 10 is the memory. The memory is a nonvolatile or volatile semiconductor memory, such as a random access memory (RAM), a read-only memory (ROM), a flash memory, or an erasable programmable ROM (EPROM), or a disk, such as a magnetic disk, a flexible disk, or an optical disk.

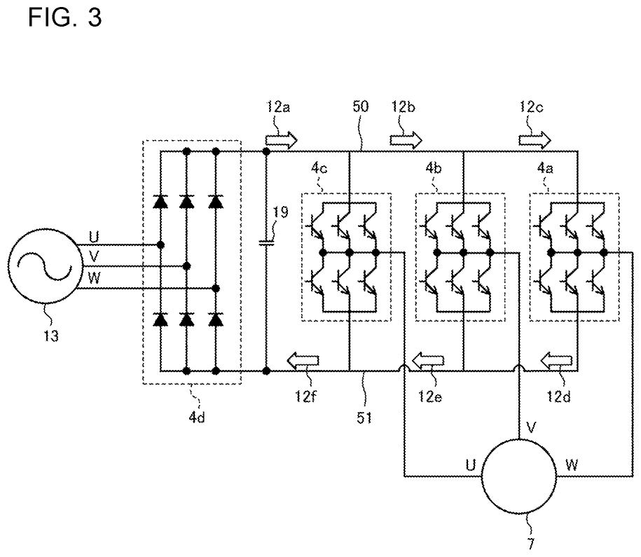

FIG. 3 is a circuit diagram illustrating a configuration of a power converter provided in the controller 5 of the air-conditioning apparatus according to Embodiment 1. The power converter includes the heating components 4a, 4b, 4c, and 4d. The power converter further includes other components 19 as needed. The other components 19 are, for example, the other components 19a to 19d as illustrated in FIG. 2. The heating components 4a, 4b, 4c, and 4d are each, for example, a converter module, a rectifier, or an inverter module. The following description is made with respect to the case where the heating component 4d is a rectifier and the heating components 4a, 4b, 4c are each an inverter module. The other components 19a to 19d are each, for example, a capacitor.

As illustrated in FIG. 3, the heating component 4d, which is a rectifier, is connected between a positive bus line 50 and a negative bus line 51. The heating component 4d is connected to an alternating-current power supply 13. The heating component 4d converts alternating current from the alternating-current power supply 13 to direct current. As illustrated in FIG. 3, the heating component 4d is a diode bridge circuit. Six diodes are provided in the heating component 4d. Specifically, in the heating component 4d, upper arm diodes and lower arm diodes are connected in series to form series units. In the heating component 4d, three series units connected in parallel are provided. The three series units are connected with respective phases of the alternating-current power supply 13, that is, the U phase, V phase, and W phase.

As illustrated in FIG. 3, the heating components 4a, 4b, and 4c, which are inverter modules, are each connected parallel to the heating component 4d. That is, the heating component 4a is connected between the positive bus line 50 and the negative bus line 51. Similarly, the heating component 4b is connected between the positive bus line 50 and the negative bus line 51. Similarly, the heating component 4c is connected between the positive bus line 50 and the negative bus line 51. Direct current from the heating component 4d flows through the heating components 4a, 4b, and 4c. The heating components 4a, 4b, and 4c convert the direct current to alternating currents with different frequencies. The heating components 4a, 4b, and 4c are connected to a motor of the compressor 7. The three heating components 4a, 4b, and 4c are connected with respective phases of the motor of the compressor 7, that is, the W phase, V phase, and U phase.

As illustrated in FIG. 3, the heating component 4a is a full-bridge circuit. As illustrated in FIG. 3, six switching elements are provided in the heating component 4a. With each of the switching elements, a free-wheeling diode (not illustrated) is connected in anti-parallel. The switching element is, for example, an insulated gate bipolar transistor (IGBT) or a metal oxide semiconductor field effect transistor (MOSFET). In the heating component 4a, upper arm switching elements and lower arm switching elements are connected in series to form series units. In such a manner, the heating component 4a includes three series units each of which is made up of a pair of upper and lower arm switching elements. These series units are connected in parallel.

As illustrated in FIG. 3, the heating component 4b is a full-bridge circuit. As illustrated in FIG. 3, six switching elements are provided in the heating component 4b. With each of the switching elements, a free-wheeling diode (not illustrated) is connected in anti-parallel. The switching element is, for example, an IGBT or a MOSFET. In the heating component 4b, upper arm switching elements and lower arm switching elements are connected in series to form series units. In such a manner, the heating component 4b includes three series units each of which is made up of a pair of upper and lower arm switching elements. These series units are connected in parallel.

As illustrated in FIG. 3, the heating component 4c is a full-bridge circuit. As illustrated in FIG. 3, six switching elements are provided in the heating component 4c. With each of the switching elements, a free-wheeling diode (not illustrated) is connected in anti-parallel. The switching element is, for example, an IGBT or a MOSFET. In the heating component 4c, upper arm switching elements and lower arm switching elements are connected in series to form series units. In such a manner, the heating component 4c includes three series units each of which is made up of a pair of upper and lower arm switching elements. These series units are connected in parallel.

The heating components 4a to 4c form a single inverter. In a known inverter that converts direct current to three-phase alternating current, for each of phases, a pair of upper and lower arm switching elements are provided. In contrast, in the inverter of Embodiment 1, for each phase, three pairs of upper and lower arm switching elements are provided. The control module 10 produces a PWM signal on the assumption that three pairs of upper and lower arm switching elements are a single set of upper and lower arm switching elements having a large current capacity. Each of the switching elements of the heating components 4a to 4c performs an on-off operation in response to the PWM signal.

As illustrated in FIG. 3, a capacitor 19 is provided between the heating component 4d and the heating component 4c. The capacitor 19 is connected in parallel with the heating component 4d and the heating component 4c. The number of capacitors 19 may be one or may be two or more. As described above, referring to FIG. 2, the components 19a to 19d are, for example, capacitors. The components 19a to 19d form the capacitor 19 provided as illustrated in FIG. 3. The capacitor 19 as illustrated FIG. 3 may be made of a single component or may be made up of the components 19a to 19d as illustrated in FIG. 2.

Furthermore, a reactor may be connected in series to the positive bus line 50 between the heating component 4d and the heating component 4c, as needed. It is preferable that the reactor be provided closer to the alternating-current power supply 13 than to the capacitor 19. In the case where the reactor is provided, direct current output from the heating component 4d is input to the heating components 4a to 4c via the reactor. Regarding Embodiment 1, the above description is made on the assumption that the capacitor 19 is included in the power converter, but it is not limiting. The capacitor 19 may be provided outside the power converter. Regarding the case where the reactor is provided, the above description is made on the assumption that the reactor is included in the power converter, but is it not limiting. The reactor may be provided outside the power converter.

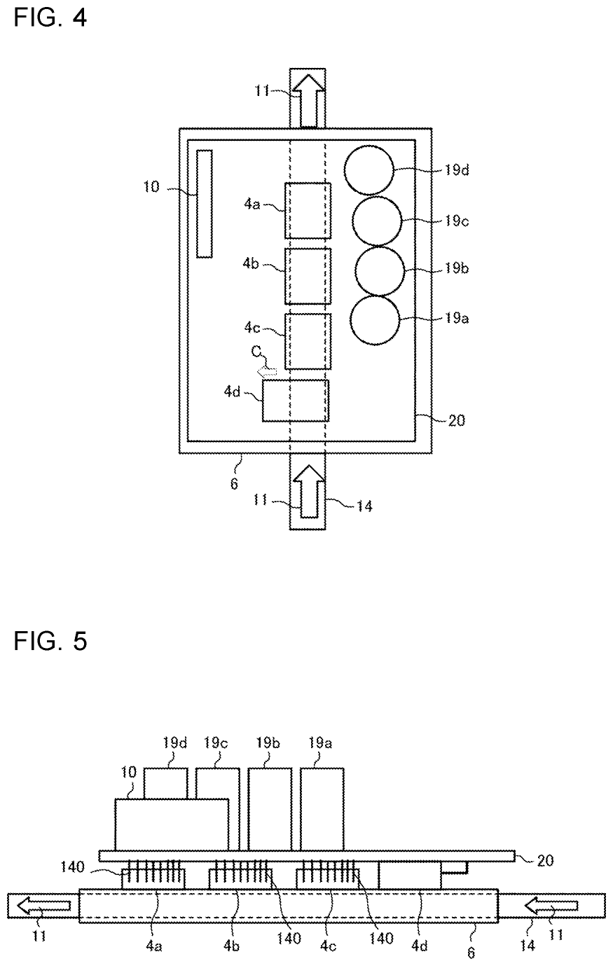

FIG. 4 is a plan view illustrating an internal configuration of the controller 5 of the air-conditioning apparatus according to Embodiment 1. FIG. 5 is a side view illustrating the internal configuration of the controller 5 of the air-conditioning apparatus according to Embodiment 1. In FIGS. 4 and 5, illustration of the housing 5a of the controller 5 is omitted. The heating components 4a to 4d are provided on the lower surface of the substrate 20 as illustrated in FIG. 5, and should thus be indicated by dashed lines in FIG. 4. However, if the heating components 4a to 4d were indicated by the dashed lines, the heating components 4a to 4d could not easily be recognized. Thus, in FIG. 4, the heating components 4a to 4d are indicated by solid lines.

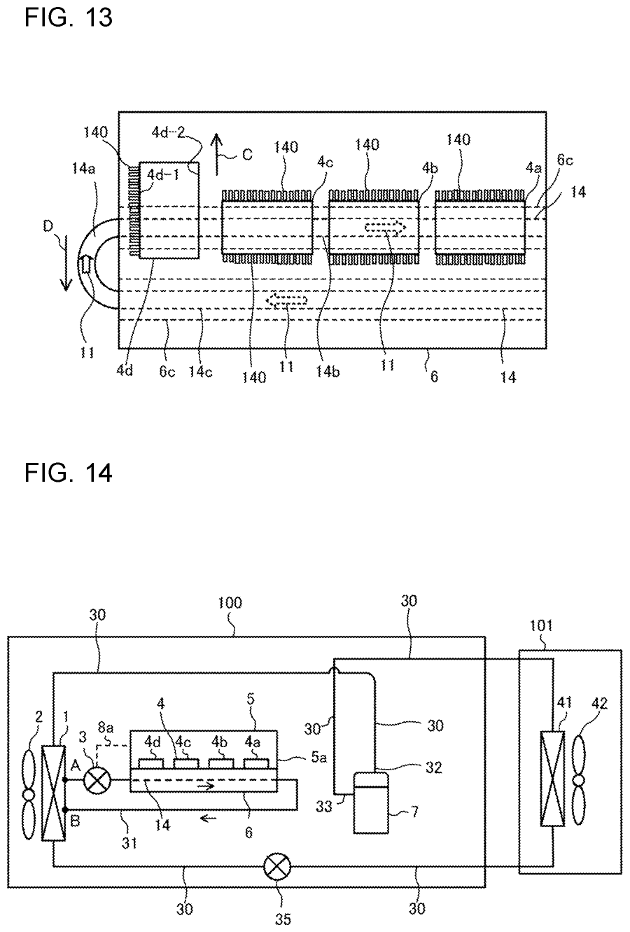

FIGS. 4 and 5 indicate a positional relationship between the cooling refrigerant pipe 14 attached to the cooling plate 6 and each of the heating components 4a to 4d. As illustrated in FIG. 5, the cooling plate 6 is provided to face the substrate 20 and in parallel with the substrate 20, and is in close contact with one surface of each of the heating components 4a to 4d. The cooling plate 6 is in contact with the heating components 4a to 4d and the cooling refrigerant pipe 14, and is thermally connected to the heating components 4a to 4d and the cooling refrigerant pipe 14. As illustrated in FIGS. 4 and 5, the cooling refrigerant pipe 14 is provided in such a manner as to extend through the inside of the cooling plate 6. This, however, is not limiting. The cooling refrigerant pipe 14 may be provided on an outer surface of the cooling plate 6. Alternatively, a groove may be provided in the cooling plate 6, and the cooling refrigerant pipe 14 may be accommodated in the groove. In any case, since the cooling plate 6 uses refrigerant 11 to cool the heating components 4a to 4d, it is preferable that at least part of the cooling plate 6 be provided between the heating components 4a to 4d and the cooling refrigerant pipe 14. The cooling refrigerant pipe 14 is attached to the cooling plate 6 by brazing or other methods, such that the cooling refrigerant pipe 14 is in direct contact with the cooling plate 6. The cooling refrigerant pipe 14 is, for example, made of metal having a high thermal conductivity, such as copper and aluminum. The cooling refrigerant pipe 14 may be attached to the cooling plate 6, with for example, a seal member interposed between the cooling refrigerant pipe 14 and the cooling plate 6, that is, the cooling refrigerant pipe 14 is in indirect with the cooling plate 6. It should be noted that although FIGS. 4 and 5 each illustrates by way of example a configuration in which the single cooling refrigerant pipe 14 is attached to the plate-shaped cooling plate 6, this illustration is not limiting. That is, the number of the cooling plates 6, the shape of the cooling plate 6, the number of the cooling refrigerant pipes 14, and the shape of the cooling refrigerant pipe 14 may be changed as needed. FIG. 13, which will be described later, illustrates an example in which two cooling refrigerant pipes 14 are provided in the cooling plate 6.

As illustrated in FIGS. 4 and 5, the refrigerant 11 flows in the cooling refrigerant pipe 14. As illustrated in FIG. 4, on the cooling plate 6, the heating components 4a to 4d are provided in a region that overlaps with the cooling refrigerant pipe 14, as seen in plan view. The heating components 4d, 4c, 4b, and 4a are arranged in a line in the flow direction of the refrigerant 11 in the cooling refrigerant pipe 14. As illustrated in FIG. 4, the longitudinal direction of the heating components 4a to 4c is parallel to the flow direction of the refrigerant 11. In addition, the center position of the heating components 4a to 4c in the widthwise direction coincides with the center position of the cooling refrigerant pipe 14 in the radial direction of the cooling refrigerant pipe 14. The radial direction of the cooling refrigerant pipe 14 is a width direction thereof as the cooling refrigerant pipe 14 is seen in plan view as illustrated in FIG. 4, and is also a direction perpendicular to the flow direction of the refrigerant 11. By contrast, the heating component 4d is provided such that the widthwise direction of the heating component 4d is parallel to the flow direction of the refrigerant 11.

As illustrated in FIGS. 4 and 5, refrigerant 11 flows in parallel with the heating components 4d, 4c, 4b, and 4a arranged in a line. Therefore, the heating components 4a to 4d are cooled in the following order: the heating component 4d, the heating component 4c, the heating component 4b, and the heating component 4a. When the heating components 4a to 4d are cooled, the refrigerant 11 receives the heat of the heating components 4a to 4d. Thus, the temperature of the refrigerant 11 rises as the refrigerant 11 moves away from the inflow side of the refrigerant 11. Therefore, the cooling performance of the refrigerant 11 is the highest when the refrigerant 11 cools the heating component 4d, and is the lowest when the refrigerant 11 cools the heating component 4a. Thus, in the case where the temperatures of heat generated by the heating components 4a to 4c are equal to each other, as the result of the cooling, the temperatures of the heating components 4a to 4c satisfy the following relationship: the temperature of the heating component 4a>the temperature of the heating component 4b>the temperature of the heating component 4c.

As illustrated in FIG. 4, the heating components 4a to 4c are provided such that the longitudinal direction of the heating components 4a to 4c is parallel to the flow direction of the refrigerant 11. Therefore, the distance by which the heating components 4a to 4c overlap with the cooling refrigerant pipe 14 is increased. By contrast, in the case where the heating components 4a to 4c are provided such that the widthwise direction thereof is parallel to the flow direction of the refrigerant 11, the distance by which the heating components 4a to 4c overlaps with the cooling refrigerant pipe 14 is decreased. Therefore, in Embodiment 1, the heating components 4a to 4c are provided such that the longitudinal direction of the heating components 4a to 4c is parallel to the flow direction of the refrigerant 11. Thus, the distance by which the heating components 4a to 4c overlap with the cooling refrigerant pipe 14 is increased and cooling of the heating components 4a to 4c is facilitated.

By contrast, the amount of heat generated by the heating component 4d is smaller than those by the heating components 4a to 4c. Therefore, of the heating components 4a to 4d, the heating component 4d is a component that is the most difficult to raise the temperature of it to a high level. Therefore, the heating component 4d originally does not need to be cooled so much. Although it depends on a temperature condition, the heating component 4d may be cooled more than necessary, and as a result, condensation may occur on the surface of the heating component 4d. Therefore, as illustrated in FIG. 4, the heating component 4d is provided in such a manner as to satisfy the following positional relationships (i) and (ii).

(i) The heating component 4d is provided such that the widthwise direction of the heating component 4d is parallel to the flow direction of the refrigerant 11.

(ii) The center position of the heating component 4d in the longitudinal direction thereof is offset in a direction indicated by an arrow C from the center position of the cooling refrigerant pipe 14 in the radial direction thereof.

Because of the above relationship (i), the distance by which the heating component 4d overlaps with the cooling refrigerant pipe 14 is decreased, and cooling of the heating component 4d is reduced.

Because of the above relationship (ii), the center position of the heating component 4d in the longitudinal direction is offset from the cooling refrigerant pipe 14. It is therefore possible to prevent the heating component 4d from being cooled as a whole.

In such a manner, it is possible to prevent the heating component 4d from being excessively cooled, because of the above relationships (i) and (ii). As a result, it is also possible to prevent occurrence of condensation on the surface of the heating component 4d.

It should be noted that the heating components 4a to 4c will also be referred to as first heating components, and the heating component 4d will also be referred to as a second heating component that generates a smaller amount of heat than the first heating components. In this case, the first heating components are provided such that the longitudinal direction of the first heating components is parallel to the flow direction of the refrigerant 11. By contrast, the second heating component is provided such that the widthwise direction of the second heating component is parallel to the flow direction of the refrigerant 11. In addition, it is more preferable that the center position of the second heating component in the longitudinal direction be offset from the cooling refrigerant pipe 14. Thus, cooling of the first heating components, which generate a larger amount of heat, is facilitated, and cooling of the second heating component, which generates a smaller amount of heat, is reduced. As a result, the first heating components are sufficiently cooled, and the second heating component can be cooled without causing condensation.

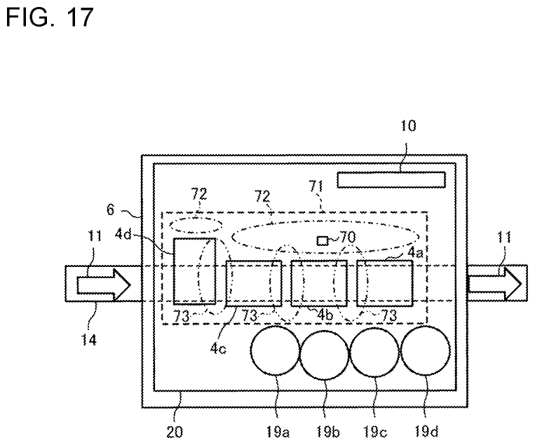

As described above, in Embodiment 1, as illustrated in FIGS. 2 and 4, the heating component 4d, which is provided on the most upstream side, is located such that the longitudinal direction of the heating component 4d is perpendicular to the longitudinal direction of the other three heating components, and the heating components 4a to 4d are provided in proximity to each other. The heating components 4a to 4d are arranged in a line at central part of the substrate 20. The central part of the substrate 20 is central part thereof in the width direction as the substrate 20 is seen in plan view as illustrated in FIG. 4 and is central part of the substrate 20 in a direction perpendicular to the flow direction of the refrigerant 11. In such a manner, since the heating components 4a to 4d are mounted on the central part of the substrate 20, the substrate 20 is not easily warped and the overall rigidity of the substrate 20 is improved to a high level. Therefore, even when stress acts on the substrate 20, the substrate 20 is not easily warped, and the stress that acts on components mounted on the substrate 20 can be reduced to less than or equal to a proof strength. This will be described in detail with reference to FIG. 17. FIG. 17 is a plan view illustrating the case where a “smaller peripheral component 70” is mounted on the substrate 20 formed as illustrated in FIG. 2. The “smaller peripheral component 70” is, for example, a chip capacitor, such as a ceramic capacitor.

In recent years, a control substrate (that is, the substrate 20) has been made smaller, and accordingly, peripheral components mounted on the control substrate have also been made smaller. In a manufacturing process or other processes, for example, when the substrate 20 is attached to the inside of the housing 5a of the controller 5, or when a connector (not illustrated) provided at the substrate 20 is inserted or removed, a load may be applied to part of the substrate 20. In this case, the substrate 20 is warped, and distortion occurs at some portions of the substrate 20. In the substrate 20, in the case where the “smaller peripheral component 70” is mounted at a location, when the amount of distortion that occurs at the above location exceeds a limit value, a stress higher than or equal to a proof strength is applied to the “smaller peripheral component 70” and as a result, a crack appears in the “smaller peripheral component” and a failure occurs. Therefore, in the substrate 20, it is necessary to reduce the amount of distortion at the above location of the “smaller peripheral component 70” to a level that is below the limit value.

Therefore, in Embodiment 1, as illustrated in FIGS. 2 and 17, the heating components 4a to 4d are arranged in the longitudinal direction of the substrate 20 on the central part of the substrate 20. Because of this configuration, distortion does not easily occur at the substrate 20. Thus, in the manufacturing process or other processes of the substrate 20, it is possible to prevent generation of a stress that exceeds the proof strength of the “smaller peripheral component 70” in the substrate 200, and protect the “smaller peripheral component 70”.

In a region 71 including a region in which the heating components 4a to 4d are provided and the periphery of the region, as illustrated in FIG. 17, a plurality of small electrical components including the “smaller peripheral component 70” are present. The following description is made by referring to by way of example the case where in the region 71, the “smaller peripheral component 70” is provided in a region 72 adjacent to the region in which the heating components 4a to 4d are provided. Referring to FIG. 17, the regions 72 and regions 73 are included in the region 71. The regions 72 are regions adjacent to the region in which the heating components 4a to 4d are provided. The regions 73 are regions between the heating components 4a to 4d.

As illustrated in FIG. 17, as compared with the “smaller peripheral component 70”, the heating components 4a to 4d are large in size for the substrate 20. Therefore, the mounting area each of the heating components 4a to 4d on the substrate 20 is larger than the mounting area of the “smaller peripheral component 70” on the substrate 20. The heating components 4a to 4d have high rigidity and are not easily warped, as compared with the “smaller peripheral component 70”. Therefore, by mounting the heating components 4a to 4d on the central part of the substrate 20, it is possible to improve the rigidity of the substrate 20 as a whole, and prevent warping of the region 71 that is located in the vicinity of the heating components 4a to 4d.

As illustrated in FIG. 5, bodies of the heating components 4a to 4d are not in contact with the substrate 20, but connection terminals 140 (see FIGS. 5 and 13) of the heating components 4a to 4d are provided on the substrate 20. That is, the connection terminals 140 and wiring patterns of the heating components 4a to 4d are provided in the region 72 as illustrated in FIG. 17. The bodies of the heating components 4a to 4d are fixed in close contact with the cooling plate 6. Therefore, with the cooling plate 6, the rigidity of the heating components 4a to 4d is further increased. Since the rigidity of the heating components 4a to 4d is high and the heating components 4a to 4d are not distorted, the heating components 4a to 4d support the substrate 20 with a sufficient strength, with the connection terminals 140 interposed between the heating components 4a to 4d and the substrate 20. Therefore, in the case where the “smaller peripheral component 70” is connected to the wiring patterns of the heating components 4a to 4d and provided in the region 72, in the region 72, the substrate 20 is not distorted. It is therefore possible to prevent the “smaller peripheral component 70” from being broken because of distortion of the substrate 20. Also, in a region other than the region 72, that is, in the region 73 between the heating components 4a to 4d, the heating components 4a to 4d are mounted in proximity to each other, and thus the substrate 20 is not distorted. It is therefore possible to prevent the substrate 20 from being broken.

As described above, in Embodiment 1, the heating component 4d provided on the most upstream side is located such that the longitudinal direction of the heating component 4d is perpendicular to the longitudinal direction of the other three heating components 4a to 4c. The heating components 4a to 4d are provided in proximity to each other. In addition, the heating components 4a to 4d are arranged on the central part of the substrate 20. Therefore, it is possible to prevent distortion of the substrate 20 in a wide range including not only the region in which the heating components 4a to 4d are provided but also the region 71 including the periphery of the above region. As a result, even in the case where the “smaller peripheral component 70” is provided at a position located apart from the heating components 4a to 4d, for example, the region 72 or the region 73, it is possible to prevent generation of a stress that exceeds the proof strength of the “smaller peripheral component 70”.

In addition, in Embodiment 1, the heating components 4a to 4d are mechanically bonded to the cooling plate 6. Thus, the rigidity of the heating components 4a to 4d is increased by the cooling plate 6, and it is further effective in prevention of distortion of the substrate 20.

Next, the operation of the air-conditioning apparatus according to Embodiment 1 will be described. The following description is made with respect to the operation of the air-conditioning apparatus in the case where the air-conditioning apparatus is in cooling operation. The description of the operation of the air-conditioning apparatus in the case where the air-conditioning apparatus is in heating operation will be omitted.

As illustrated in FIG. 1, refrigerant sucked from the suction port of the compressor 7 is compressed in the compressor 7, and is then discharged from the compressor 7 and flows to the heat exchanger 1 of the outdoor unit 100. The refrigerant is cooled by air sent from the outdoor-unit fan 2 in the heat exchanger 1. At this time, the refrigerant flows from the connection point A, which is located at a given position between the heat exchanger 1 that operates as a condenser and the suction port 33 of the compressor 7, toward the cooling refrigerant pipe 14 via the bypass pipe 31.

The refrigerant that has flowed into the cooling refrigerant pipe 14 cools the heating components 4a to 4d attached to the cooling plate 6 and then joins refrigerant that flows through the refrigerant pipe 30 toward the suction port 33 of the compressor 7, at the connection point B, which is located at a given position between the heat exchanger 1 that operates as a condenser and the suction port 33 of the compressor 7, whereby these refrigerants combine into single refrigerant. The refrigerant is sucked into the compressor 7 from the suction port 33 of the compressor 7. As described above, whether or not to cause refrigerant 11 to flow in the cooling refrigerant pipe 14 can be switched by control of the refrigerant flow control device 3 by the control module 10.

Next, current that flows through the heating components 4a to 4d will be described with reference to FIG. 3. This will also be described by referring to by way of example the case where the heating component 4d is a rectifier and the heating components 4a to 4c are each an inverter module. As illustrated in FIG. 3, first, alternating current from the alternating-current power supply 13 is input to the heating component 4d that is a rectifier. The heating component 4d converts alternating current to a direct current. Subsequently, the direct current output from the heating component 4d flows through the heating components 4a to 4c that are inverter modules. As described above, the heating components 4a to 4c that are inverter modules are connected in parallel with the heating component 4d that is a rectifier.

In the power converter, circuit currents 12a to 12f flow through the positive bus line 50 and the negative bus line 51 as indicated by the arrows in FIG. 3. It should be noted that the circuit current 12a is a circuit current that flows through the positive bus line 50 between the heating component 4d and the heating component 4c. The circuit current 12b is a circuit current that flows through the positive bus line 50 between the heating component 4c and the heating component 4b. The circuit current 12c is a circuit current that flows through the positive bus line 50 between the heating component 4b and the heating component 4a. The circuit current 12d is a circuit current that flows through the negative bus line 51 between the heating component 4a and the heating component 4b. The circuit current 12e is a circuit current that flows through the negative bus line 51 between the heating component 4b and the heating component 4c. The circuit current 12f is a circuit current that flows through the negative bus line 51 between the heating component 4c and the heating component 4d.

At this time, the circuit currents 12a to 12f as illustrated in FIG. 3 are as follows. The circuit current 12c and the circuit current 12d flow through only the heating component 4a. The circuit current 12b and the circuit current 12e flow through the heating component 4a and the heating component 4b. The circuit current 12a and the circuit current 12f flow through the heating components 4a, 4b, and 4c. Therefore, the relationship between the magnitudes of current values of the circuit currents 12a to 12f satisfies (the current values of the circuit currents 12a, 12f)>(the current values of the circuit currents 12b, 12e)>(the current values of the circuit currents 12c, 12d). It should be noted that the current values of currents that flow through the heating components 4a, 4b, 4c are equal to each other, and the magnitudes of heat losses that occur in the heating components 4a to 4c are also equal to each other. However, since the heating components 4a to 4c are connected to current paths through which the circuit currents 12a to 12f flow, the heating components 4a to 4c are affected by heat losses due to the flow of the circuit currents 12a to 12f. Thus, the relationship between the temperatures of the heating components 4a to 4c satisfies (the temperature of the heating component 4c)>(the temperature of the heating component 4b)>(the temperature of the heating component 4a).

As described with reference to FIGS. 4 and 5, it is assumed that the temperatures of heat generated by the heating components 4a to 4d are equal to each other. At this time, the relationship between the temperatures of the heating components 4a to 4d satisfies (the temperature of the heating component 4d)>(the temperature of the heating component 4c)>(T the temperature of the heating component 4b)>(the temperature of the heating component 4a) due to refrigerant 11 and the circuit currents 12a to 12f.

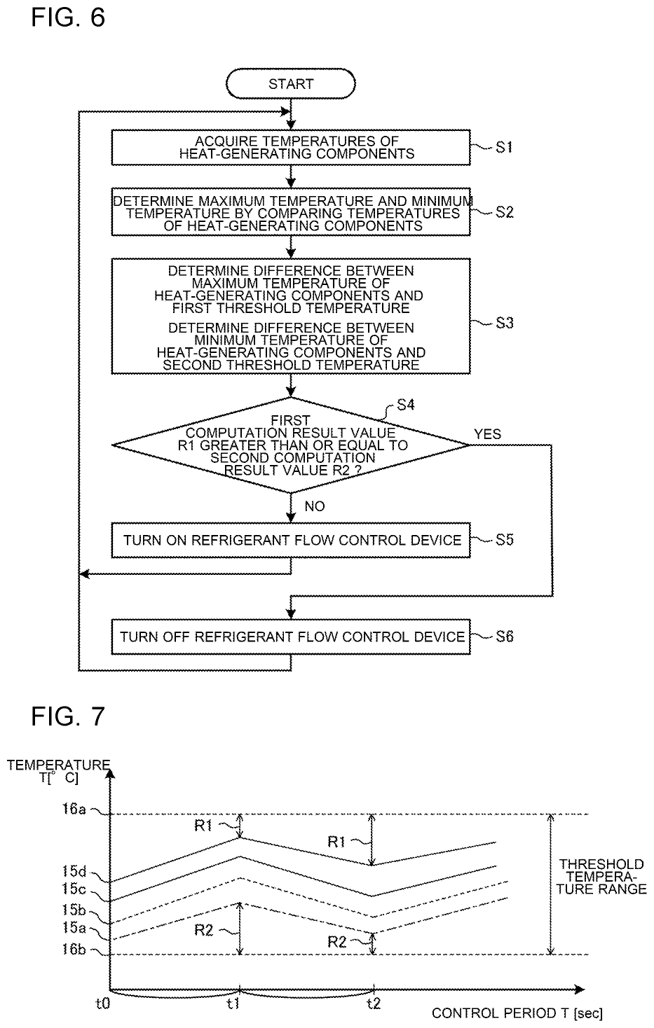

FIG. 6 is a diagram indicating a control flow of the control module 10 of the air-conditioning apparatus according to Embodiment 1. FIG. 6 illustrates the operation of the control module 10 in the case where the control module 10 controls the refrigerant flow control device 3. FIG. 7 is a diagram indicating an example of a temperature change graph for an explanation of the flowchart of FIG. 6.

In FIG. 7, reference sign 16a denotes a first threshold temperature, and reference sign 16b denotes a second threshold temperature. The first threshold temperature 16a is determined based on, for example, the heat resisting temperature of the heating components 4a to 4d. Alternatively, the first threshold temperature 16a may be determined based on temperature differences among the heating components 4a to 4d.

Furthermore, the second threshold temperature 16b is determined based on, for example, the condensation temperature of the cooling plate 6. Alternatively, the second threshold temperature 16b may be determined based on the heat resisting temperature of the heating components 4a to 4d, or the ambient temperature of the outdoor unit 100, or the average refrigerant temperature of refrigerant 11. In FIG. 7, reference sign 15a denotes the temperature of the heating component 4a, and reference sign 15b denotes the temperature of the heating component 4b. Reference sign 15c denotes the temperature of the heating component 4c, and reference sign 15d denotes the temperature of the heating component 4d. The flow as indicated in FIG. 6 is repeatedly executed at intervals of a control period T.

In the control flow as indicated in FIG. 6, the control module 10 determines switching between the ON-state and the OFF-state of the refrigerant flow control device 3.

In step S1, the control module 10 acquires temperature information 8b from the temperature detectors 21a to 21d. The control module 10 acquires the temperatures 15a to 15d of the heating components 4a to 4d based on the temperature information 8b.

Subsequently, in step S2, the control module 10 compares the temperatures 15a to 15d of the heating components 4a to 4d to determine a maximum value, and determines the maximum value as the maximum temperature of the heating components 4a to 4d. Also, the control module 10 compares the temperatures 15a to 15d of the heating components 4a to 4d to determine a minimum value, and determines the minimum value as the minimum temperature of the heating components 4a to 4d. This will be described with reference to the example indicated in FIG. 7. At time t1, the maximum temperature is the temperature 15d of the heating component 4d, and the minimum temperature is the temperature 15a of the heating component 4a, and at time t2, the maximum temperature is the temperature 15d of the heating component 4d, and the minimum temperature is the temperature 15a of the heating component 4a.

After that, in step S3, the control module 10 determines an absolute value of the difference between the maximum temperature and the first threshold temperature 16a and determines the absolute value of the difference as a first computation result value R1. Also, the control module 10 determines an absolute value of the difference between the minimum temperature and the second threshold temperature 16b, and determines the absolute value of the difference as a second computation result value R2.

Next, in step S4, the control module 10 compares the first computation result value R1 with the second computation result value R2. When the first computation result value R1 is greater than or equal to the second computation result value R2, the process by the control module 10 proceeds to the process of step S6. By contrast, when the first computation result value R1 is less than the second computation result value R2, the process by the control module 10 proceeds to the process of step S5.

In step S5, since the temperatures 15a to 15d of the heating components 4a to 4d are generally high, the control module 10 causes the refrigerant flow control device 3 to be in the ON-state (opened state) to allow the refrigerant 11 to flow in the cooling refrigerant pipe 14. Thus, the refrigerant 11 flows through the cooling refrigerant pipe 14. As a result, the heating components 4a to 4d are cooled by the refrigerant 11.

In step S6, since the temperatures 15a to 15d of the heating components 4a to 4d are generally low, the control module 10 causes the refrigerant flow control device 3 to be in the OFF (closed state) to stop the flow of the refrigerant 11 in the cooling refrigerant pipe 14. Thus, refrigerant 11 does not flow through the cooling refrigerant pipe 14. As a result, the heating components 4a to 4d are not cooled by the refrigerant 11.

The above will be described by referring to the example as indicated in FIG. 7. At time T1, when the first computation result value R1 is compared with the second computation result value R2, the first computation result value R1 is less than the second computation result value R2, and the refrigerant flow control device 3 is thus set in the ON-state. At time t2, when the first computation result value R1 is compared with the second computation result value R2, the first computation result value R1 is greater than or equal to the second computation result value R2, and the refrigerant flow control device 3 is thus set in the OFF-state.

In such a manner, the control module 10 controls switching between the ON-state and the OFF-state of the refrigerant flow control device 3 in accordance with the control flow of FIG. 6. Thus, as illustrated in FIG. 7, the temperatures 15a to 15d of the heating components 4a to 4d always fall within the range between the first threshold temperature 16a and the second threshold temperature 16b. The range between the first threshold temperature 16a and the second threshold temperature 16b will be referred to as a threshold temperature range. Therefore, the first threshold temperature 16a is the upper limit value of the threshold temperature range, and the second threshold temperature 16b is the lower limit value of the threshold temperature range. The control module 10 switches the state of the refrigerant flow control device 3 between the ON-state and the OFF-state such that the temperatures 15a to 15d respectively detected by the temperature detectors 21a to 21d always fall within the threshold temperature range.

In the control flow as indicated in FIG. 6, the first computation result value R1 is compared with the second computation result value R2. This, however, is not limiting. For example, the first computation result value R1 may be compared with a threshold set in advance. In this case, when the first computation result value R1 is less than the threshold, the control module 10 causes the refrigerant flow control device 3 to be in the ON-state, and when the first computation result value R1 is greater than or equal to the threshold, the control module 10 causes the refrigerant flow control device 3 to be in the OFF-state. For example, regarding the example as indicated in FIG. 7, it is assumed that at time t1, the first computation result value R1 is less than the threshold. In this case, the control module 10 causes the refrigerant flow control device 3 to be in the ON-state. Also, it is assumed that at time t2, the first computation result value R1 is greater than or equal to the threshold. In this case, the control module 10 causes the refrigerant flow control device 3 to be in the OFF-state.

In such a manner, in Embodiment 1, the cooling plate 6 cools the heating components 4a to 4d of the control module 10, using part of refrigerant 11 flowing from the heat exchanger 1 that operates as a condenser, toward the suction port 33 of the compressor 7. Thus, it is possible to cool the heating components 4a to 4d, and prevent breakage of the “smaller peripheral component 70” from occurring because of the heat of the heating components 4a to 4d. As illustrated in FIGS. 1 and 14 to 16, the both ends of the bypass pipe 31 through which refrigerant 11 for use in cooling flows may be respectively connected to two given locations on the low-pressure side between the condenser and the suction port 33 of the compressor 7.

In Embodiment 1, the temperature detectors 21a to 21d are provided at the heating components 4a to 4d. The control module 10 switches the state of the refrigerant flow control device 3 between the ON-state and the OFF-state based on the temperatures 15a to 15d of the heating components 4a to 4d that are detected by the temperature detectors 21a to 21d. Thus, it is possible to appropriately cool the heating components 4a to 4d as needed.

In the description concerning Embodiment 1, the heating components 4a to 4c that generate a larger amount of heat are also referred to as the first heating components, and the heating component 4d that generates a smaller amount of heat are also referred to as the second heating component. The first heating components are each provided such that the longitudinal direction of the first heating components is parallel to the flow direction of the refrigerant 11, and the second heating component is provided such that the widthwise direction of the second heating component is parallel to the flow direction of the refrigerant 11. In such a manner, the first heating component and the second heating component are oriented in different directions. Thus, the first heating component is cooled by the refrigerant 11 for a longer time period, and the entire first heating component is sufficiently cooled. By contrast, the second heating component is cooled by the refrigerant 11 for a shorter time period, and it is thus possible to prevent the second heating component from being excessively cooled. Therefore, it is possible to prevent occurrence of condensation on the second heating component. In such a manner, in Embodiment 1, by providing the heating components 4a to 4d in a specific manner, it is possible to cool the heating components 4a to 4d while preventing occurrence of condensation with a simple configuration. Therefore, it is not necessary to provide an additional component, such as a solenoid valve for prevention of occurrence of condensation as described in Patent Literature 1. Accordingly, the configuration is simplified, and the manufacturing cost is reduced.

The cooling performance of the refrigerant 11 is the lowest when the refrigerant 11 flows as gas refrigerant. In this case, there is a possibility that the heating component 4a located at the most downstream side will not be sufficiently cooled. In order to avoid this, in Embodiment 1, the first heating components are provided such that the longitudinal direction of the first heating components is parallel to the flow direction of the refrigerant 11. Thus, it is also possible to sufficiently cool the heating components 4a to 4c. By contrast, the cooling performance of refrigerant 11 is the highest when the refrigerant 11 flows as liquid refrigerant. In this case, there is a possibility that condensation will occur at the heating component 4d located on the most upstream side. In order to avoid this, in Embodiment 1, the second heating component is provided such that the widthwise direction of the second heating component is parallel to the flow direction of the refrigerant 11. As a result, in Embodiment 1, regardless of whether the refrigerant 11 is liquid refrigerant or gas refrigerant, it is possible to sufficiently cool all the heating components 4a to 4d while preventing occurrence of condensation.

In Embodiment 1, the center position of the second heating component in the longitudinal direction is offset from the center position of the cooling refrigerant pipe 14 in the radial direction. Thus, it is possible to prevent the second heating component from being cooled as a whole. This is thus more appropriate.

In Embodiment 1, as illustrated in FIG. 4, in the flow direction of the refrigerant 11, the heating component 4c is provided on the upstream side, and the heating component 4a is provided on the downstream side. In such a manner, since the value of a current that flows the heating component 4c is higher than the value of a current that flows toward the heating component 4a, it is preferable that the heating component 4c be provided on the upstream side and the heating component 4a be provided on the downstream side in the flow direction of the refrigerant 11. Thus, the temperature differences between the heating components 4a to 4c are reduced. As described above, it is possible to more efficiently cool the heating components 4a to 4c by arranging the heating components 4a to 4c in the following manner: the heating components 4a to 4c, the heating component that generates the largest amount of heat is provided on the most upstream side in the flow direction of the refrigerant 11, and the heating component that generates the smallest amount of heat among the heating components 4a to 4c is provided on the most downstream side in the flow direction of the refrigerant 11.

In Embodiment 1, on the central part of the substrate 20, the heating components 4a to 4d are arranged in the longitudinal direction of the substrate 20. Because of this configuration, the rigidity of the substrate 20 is increased, the substrate 20 is not distorted in the region 71 around the region in which the heating components 4a to 4d are provided. As a result, it is possible to prevent a stress exceeding the proof strength from acting on small electrical components including the “smaller peripheral component 70” provided in the region 71. Thus, it is possible to prevent breakage of the small electrical components provided in the region 71.

The above description regarding Embodiment 1 refers to the example in which the control module 10 switches the state of the refrigerant flow control device 3 between the ON-state and the OFF-state. This, however, is not limiting. The control module 10 may adjust the flow path leading to the cooling refrigerant pipe 14 by controlling the opening degree of the refrigerant flow control device 3 based on the temperature information 8b. In this case, the control module 10 stores in a memory in advance a table in which the opening degree of the refrigerant flow control device 3 is determined in advance for the maximum temperature or minimum temperature of each of the temperatures 15a to 15b of the heating components 4a to 4d. The control module 10 obtains the maximum temperature or minimum temperature of the temperatures 15a to 15b of the heating components 4a to 4d based on the temperature information 8b. The control module 10 obtains the opening degree of the refrigerant flow control device 3 from the table based on the obtained maximum temperature or minimum temperature, and controls the opening degree of the refrigerant flow control device 3.

In Embodiment 1, the layout of the heating components 4a to 4d on the substrate 20 is made coincide with the layout of an electrical circuit as illustrated in FIG. 3. To be more specific, as illustrated in FIG. 3, the heating components 4d, 4c, 4b, and 4a are electrically connected in this order. Therefore, on the substrate 20, the heating components 4d, 4c, 4b, and 4a are also provided in this order. That is, the heating components 4a to 4d are provided on the substrate 20 in an order in which the heating components 4a to 4d are connected in the above manner. In such a manner, since the heating components 4a to 4d are provided on the substrate 20 in agreement with the layout of the electrical circuit, signal lines, etc., are shorten, and it is possible to efficiently dispose the heating components 4a to 4d, the components 19a to 19d, etc.

In addition, in Embodiment 1, the refrigerant 11 is caused to flow in the direction in which current flows in the electrical circuit as illustrated in FIG. 3. Therefore, the flow direction of the refrigerant 11 is parallel to the flow direction of the current. In the electrical circuit as illustrated in FIG. 3, of current flowing through the heating components 4a to 4c, current flowing through the heating component 4c for the U-phase is the largest. Therefore, it is possible to efficiently cool the heating components 4a to 4c by providing the heating component 4c for the U-phase on the most upstream side in the flow direction of the refrigerant 11.

### Embodiment 2

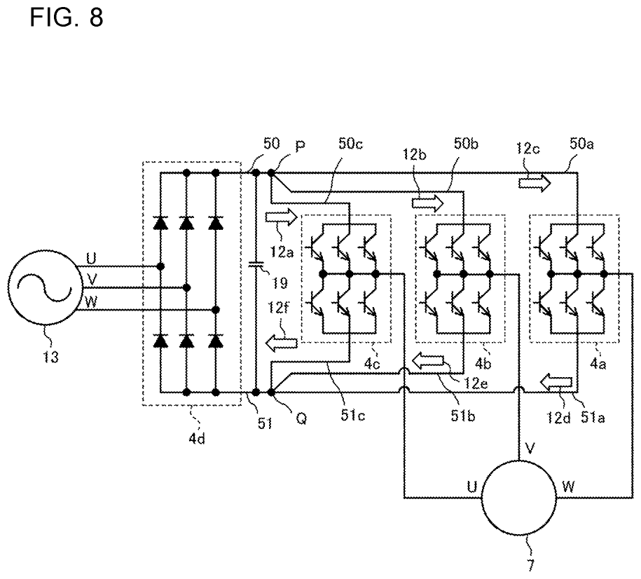

FIG. 8 is a circuit diagram illustrating a configuration of a power converter provided in the controller 5 of an air-conditioning apparatus according to Embodiment 2. The power converter includes the heating components 4a, 4b, 4c, and 4d. The heating components 4a, 4b, 4c, and 4d are each, for example, a converter module, a rectifier, or an inverter module. The following description is made by referring to by way of example the case where the heating component 4d is a rectifier and the heating components 4a, 4b, 4c are each an inverter module.

As illustrated in FIG. 8, the heating component 4d that is a rectifier is connected between the positive bus line 50 and the negative bus line 51. The heating component 4d is connected to the alternating-current power supply 13. The heating component 4d converts alternating current from the alternating-current power supply 13 to direct current. The heating component 4d includes diode bridges. As illustrated in FIG. 8, six diodes are provided in the heating component 4d. Specifically, in the heating component 4d, upper arm diodes and lower arm diodes are connected in series to form series units. In the heating component 4d, three series units connected in parallel are provided. The three series units are respectively provided for the U phase, V phase, and W phase of the alternating-current power supply 13.

As illustrated in FIG. 8, the heating components 4a, 4b, and 4c that are inverter modules are connected in parallel with the heating component 4d.

However, in an example as indicated in FIG. 8, the positive bus line 50 branches into three positive bus lines at a connection point P. The three positive bus lines will be referred to as a first positive bus line 50a, a second positive bus line 50b, and a third positive bus line 50c.

Also, in an example as illustrated in FIG. 8, the negative bus line 51 branches into three negative bus lines at a connection point Q. The three negative bus lines will be referred to as a first negative bus line 51a, a second negative bus line 51b, and a third negative bus line 51c.

In such a manner, in the example of FIG. 8, the positive bus line 50 and the negative bus line 51 branch off. In this regard, the example of FIG. 8 is different from that of FIG. 3.

As illustrated in FIG. 8, the heating component 4a is connected between the first positive bus line 50a and the first negative bus line 51a. The heating component 4b is connected between the second positive bus line 50b and the second negative bus line 51b. The heating component 4c is connected between the third positive bus line 50c and the third negative bus line 51c. Direct current from the heating component 4d flows through the heating components 4a, 4b, and 4c. The heating components 4a, 4b, and 4c convert the direct current to alternating currents having different frequencies. The heating components 4a, 4b, and 4c are connected to the compressor 7. The three heating components 4a, 4b, and 4c are provided for the W phase, V phase, and U phase of the compressor 7, respectively.

As illustrated in FIG. 8, six switching elements are provided in the heating component 4a. With each of the switching elements, a free-wheeling diode (not illustrated) is connected in anti-parallel. Each switching element is, for example, an IGBT or a MOSFET. In the heating component 4a, upper arm switching elements and lower arm switching elements are connected in series to form series units. In such a manner, the heating component 4a includes three series units each of which includes a pair of upper and lower arm switching elements. The three series units are connected in parallel.

As illustrated in FIG. 8, six switching elements are provided in the heating component 4b. With each of the switching elements, a free-wheeling diode (not illustrated) is connected in anti-parallel. Each switching element is, for example, an IGBT or a MOSFET. In the heating component 4b, upper arm switching elements and lower arm switching elements are connected in series to form series units. In such a manner, the heating component 4b includes three series units each of which includes a pair of upper and lower arm switching elements. The three series units are connected in parallel.

As illustrated in FIG. 8, six switching elements are provided in the heating component 4c. With each of the switching elements, a free-wheeling diode (not illustrated) is connected in anti-parallel. Each switching element is, for example, an IGBT or a MOSFET. In the heating component 4c, upper arm switching elements and lower arm switching elements are connected in series to form series units. In such a manner, the heating component 4c includes three series units each of which includes a pair of upper and lower arm switching elements. The three series units are connected in parallel.

The heating components 4a to 4c form a single inverter. It should be noted that a known inverter that converts direct current to three-phase alternating current includes pairs of upper and lower arm switching elements such that the upper and lower arm switching elements of each of the pairs are provided for an associated single phase. In contrast, the inverter of Embodiment 2 includes three pairs of upper and lower arm switching elements for a single phase. The control module 10 produces a PWM signal on the assumption that the three pairs of upper and lower arm switching elements are a set of upper and lower arm switching elements having a large current capacity. Each of the switching elements of the heating components 4a to 4c performs an on-off operation in response to the PWM signal.

As illustrated in FIG. 8, the capacitor 19 is provided between the heating component 4d and the heating component 4a. The capacitor 19 is connected in parallel with the heating component 4d. That is, the capacitor 19 is connected between the positive bus line 50 and the negative bus line 51. The number of capacitors 19 may be one or may be two or more. In other words, as illustrated in FIG. 2 relating to Embodiment 1, the components 19a to 19d may be respective capacitors, and the capacitor 19 may include the capacitors that are the components 19a to 19d.

In addition, between the heating component 4d and the heating component 4a, a reactor may be provided as needed. In this case, direct current output from the heating component 4d is input to the heating component 4a via the reactor. It should be noted that regarding Embodiment 2, it is described that the capacitor 19 and the reactor are included in the power converter; however, it is not limiting. The capacitor 19 and the reactor may be configured to be externally added to the power converter.

The other configuration is the same as that of Embodiment 1, and its description will be omitted.

Next, current that flows through the heating components 4a to 4d will be described with reference to FIG. 8. First, alternating current output from the alternating-current power supply 13 is input to the heating component 4d that is a rectifier. The heating component 4d converts the alternating current to direct current. Subsequently, the direct current flows to the heating components 4a to 4c that are inverter modules. At this time, the heating components 4a to 4c are connected to the heating component 4d that is a rectifier, at a point P and a point Q. Therefore, the circuit currents 12a to 12f are as follows.

It should be noted that a circuit current 12a is a current that flows through the third positive bus line 50c, and the circuit current 12f is a current that flows through the third negative bus line 51c, the circuit current 12b is a current that flows through the second positive bus line 50b, and the circuit current 12e is a current that flows through the second negative bus line 51b; and the circuit current 12c is a current that flows through the first positive bus line 50a, and the circuit current 12d is a current that flows through the first negative bus line 51a.

The circuit currents 12c and 12d flow through the heating component 4a only. The circuit currents 12b and 12e flow through the heating component 4b only. The circuit currents 12a and 12f flow through the heating component 4c only. Therefore, currents that flow through the circuit currents 12a to 12f are all equivalent to each other.

Since currents that flow through the heating components 4a, 4b, and 4c are all equivalent, the magnitudes of heat losses that occur in the heating components 4a to 4c are also equivalent. Therefore, the relationship between the temperatures of the heating components 4a to 4c satisfies (the temperature of the heating component 4a)=(the temperature of the heating component 4b)=(the temperature of the heating component 4c).

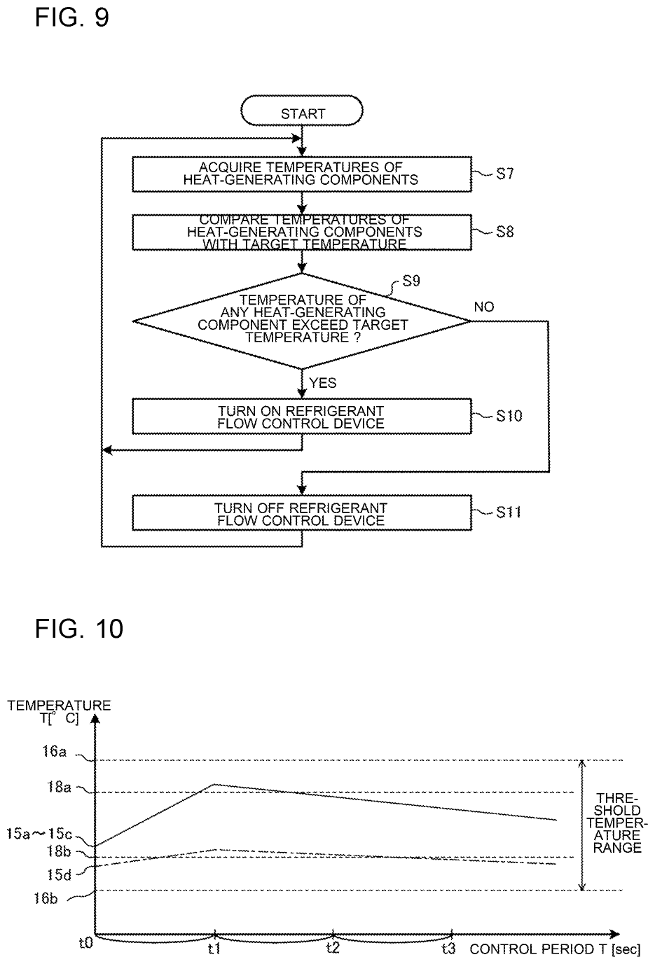

FIG. 9 is a flowchart indicating a control flow of the control module 10 of the air-conditioning apparatus according to Embodiment 2. FIG. 9 indicates the operation of the control module 10 in the case where the control module 10 controls the refrigerant flow control device 3. FIG. 10 is a view indicating an example of a temperature change graph for an explanation of the flowchart as indicated in FIG. 9.

In FIG. 10, reference sign 15a denotes the temperature of the heating component 4a ; reference sign 15b denotes the temperature of the heating component 4b ; reference sign 15c denotes the temperature of the heating component 4c ; and reference sign 15d denotes the temperature of the heating component 4d. Also, in FIG. 10, reference sign 18a denotes a first target temperature, and reference sign 18b denotes a second target temperature. The first target temperature 18a is a target value determined in advance for the temperatures 15a to 15c of the heating components 4a to 4c. The second target temperature 18b is a target value determined in advance for the temperature 15d of the heating component 4d. The first target temperature 18a is determined based on, for example, the heat resisting temperatures of the heating components 4a to 4c. Alternatively, the first target temperature 18a may be determined based on temperature differences between the heating components 4a to 4c. The second target temperature 18b is determined based on, for example, the heat resisting temperature of the heating component 4d. Alternatively, the first target temperature 18a and the second target temperature 18b may be determined based on the ambient temperature of the outdoor unit 100 or the average refrigerant temperature of refrigerant 11. The flow as indicated in FIG. 9 is repeatedly applied at intervals of a control period T.

The cooling performances of the cooling plate 6 and refrigerant 11 for the heating components 4a to 4c are equivalent to each other, and the values of currents that flow through the current paths of the heating components 4a to 4c are equivalent to each other. Therefore, it can be seen that the temperatures 15a to 15c of the heating components 4a to 4c are equal to each other and are different from only the temperature 15d of the heating component 4d. Regarding an example as indicated in FIG. 10, it is indicated that the temperature 15d is generally lower than the temperatures 15a to 15c, however, it is not limiting. That is, the temperature 15d may be generally higher than the temperatures 15a to 15c.

In the control flow as indicated in FIG. 10, the control module 10 determines switching between the ON-state and the OFF-state of the refrigerant flow control device 3.

In step S7, the control module 10 acquires temperature information 8b from the temperature detectors 21a, 21b, 21c, and 21d. The control module 10 acquires the temperatures 15a to 15d of the heating components 4a to 4d based on the temperature information 8b. At this time, since the temperatures 15a to 15c of the heating components 4a to 4c are equal to each other, the control module 10 may acquire only the temperature information 8b from the temperature detectors 21a and 21d.

Subsequently, in step S8, the control module 10 compares the temperatures 15a to 15c with the first target temperature 18a. At this time, since the temperatures 15a to 15c are equal to each other, the control module 10 may compare only the temperature 15a with the first target temperature 18a. The control module 10 compares the temperature 15d with the second target temperature 18b.

After that, in step S9, when at least one of the following two conditions (A) and (B) is satisfied, the process by the control module 10 proceeds to step S10. By contrast, when neither the condition (A) nor the condition (B) is satisfied, the process by the control module 10 proceeds to step S11.

Condition (A): The temperatures 15a to 15c exceed the first target temperature 18a.

Condition (B): The temperature 15d exceeds the second target temperature 18b.

In step S10, since the temperature of any of the heating components 4a to 4d is high, the control module 10 causes the refrigerant flow control device 3 to be in the ON-state (opened state) to allow the flow of the refrigerant 11 in the cooling refrigerant pipe 14. As a result, the refrigerant 11 flows through the cooling refrigerant pipe 14. Thus, the heating components 4a to 4d are cooled by the refrigerant 11.

In step S11, since the temperatures of the heating components 4a to 4d are all low, the control module 10 causes the refrigerant flow control device 3 to be in the OFF state (closed state) to stop the flow of refrigerant 11 in the cooling refrigerant pipe 14. Thus, the refrigerant 11 does not flow through the cooling refrigerant pipe 14. As a result, the heating components 4a to 4d are not cooled by the refrigerant 11.

The following description is made by referring to an example as indicated in FIG. 10. At time t1, when the temperatures 15a to 15c are compared with the first target temperature 18a, the temperatures 15a to 15c exceed the first target temperature 18a. Therefore, the condition (A) is satisfied. At time t1, when the temperature 15d is compared with the second target temperature 18b, the temperature 15d exceeds the second target temperature 18b. Therefore, the condition (B) is satisfied. Accordingly, the control module 10 causes the refrigerant flow control device 3 to be in the ON-state.

Referring to FIG. 10, at time t2, when the temperatures 15a to 15c are compared with the first target temperature 18a, the temperatures 15a to 15c are lower than the first target temperature 18a. Therefore, the condition (A) is not satisfied. At time t2, when the temperature 15d is compared with the second target temperature 18b, the temperature 15d exceeds the second target temperature 18b. Therefore, the condition (B) is satisfied. Therefore, the control module 10 maintains the ON-state of the refrigerant flow control device 3.

Referring to FIG. 10, at time t3, when the temperatures 15a to 15c are compared with the first target temperature 18a, the temperatures 15a to 15c are lower than the first target temperature 18a. Therefore, the condition (A) is not satisfied. At time t3, when the temperature 15d is compared with the second target temperature 18b, the temperature 15d is lower than the second target temperature 18b. Therefore, the condition (B) is not satisfied. Accordingly, the control module 10 causes the refrigerant flow control device 3 to be in the OFF-state.

In such a manner, the control module 10 controls switching between the ON-state and the OFF-state of the refrigerant flow control device 3, according to the control flow as indicated in FIG. 9. As a result, as illustrated in FIG. 10, the temperatures 15a to 15d of the heating components 4a to 4d always fall within the threshold temperature range. The control module 10 switches the state of the refrigerant flow control device 3 between the ON-state and the OFF-state such that the temperatures 15a to 15d detected by the temperature detectors 21a to 21d always fall within the threshold temperature range. The first threshold temperature 16a and the second threshold temperature 16b indicated in FIG. 10 are, for example, the same as the first threshold temperature 16a and the second threshold temperature 16b indicated in FIG. 3.

In such a manner, in Embodiment 2, it is possible to obtain advantages similar to those of Embodiment 1.

In addition, in Embodiment 2, the heating components 4a to 4c are connected to the alternating-current power supply 13 such that all the values of currents that flows through the heating components 4a to 4c are equal to each other. Thus, the magnitudes of heat losses that occur in the heating components 4a to 4c are also equal to each other. As a result, all the temperatures of the heating components 4a to 4c are equal to each other, and is different from only the temperature of the heating component 4d. Thus, the control module 10 is capable of controlling the refrigerant flow control device 3, using only two temperatures, that is, the temperature of the heating component 4a and the temperature of the heating component 4d. Therefore, it is possible to reduce the amount of calculation by the control module 10.

Regarding Embodiments 1 and 2, it is described above by way of example that the heating component 4d is a rectifier; however, it is not limiting. The heating component 4d may be a converter module that converts alternating current to direct current.

### Embodiment 3

Regarding Embodiment 3, modifications of Embodiments 1 and 2 will be described. The modifications will be described with respect to only configurations thereof that are different from those of Embodiment 1 and/or Embodiment 2. The other configurations of the modifications are the same as those of Embodiment 1 and/or Embodiment 2, and their descriptions will thus be omitted.

### Modification 1

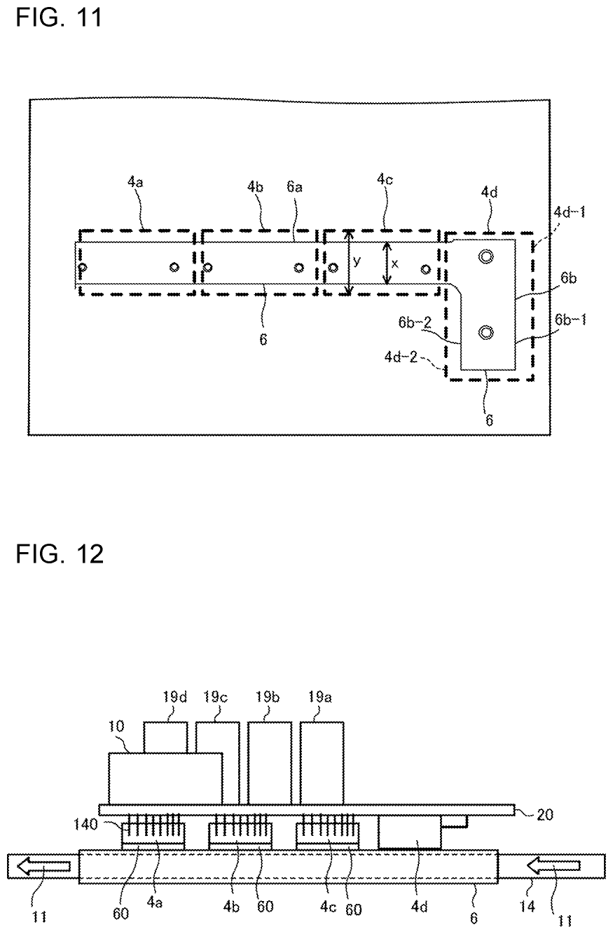

FIG. 11 is a plan view illustrating the cooling plate 6 and the heating components 4a to 4d in an air-conditioning apparatus according to Embodiment 3. As illustrated in FIG. 11, the cooling plate 6 is L-shaped as viewed in plan in accordance with the positions of the heating components 4a to 4d. To be more specific, the cooling plate 6 has a main body portion 6a that is elongated and a protrusion portion 6b that extends from the main body portion 6a in a perpendicular direction from the body portion 6a. In FIG. 11, the positions of the heating components 4a to 4d are indicated by dashed lines. In the cooling plate 6, the body portion 6a corresponds mainly to the heating components 4a to 4c, and the protrusion portion 6b corresponds to the heating component 4d. In the following, the length of the body portion 6a in the longitudinal direction is referred to as “the length of the body portion 6a”, and the length of the body portion 6a in the widthwise direction is referred to as “the width of the body portion 6a”. In the case as illustrated in FIG. 11, the cooling refrigerant pipe 14 is provided to extend in the longitudinal direction of the body portion 6a.

As illustrated in FIG. 11, where y is the length of each of the short sides of the heating components 4a to 4c, and x is the width of the body portion 6a of the cooling plate 6, the width x of the body portion 6a of the cooling plate 6 is shorter than the length y of the short sides of the heating components 4a to 4c. That is, the relationship x<y is satisfied.

As illustrated in FIG. 13, each of the heating components 4a to 4c has a plurality of connection terminals 140 on its long side. As illustrated in FIG. 5, the connection terminals 140 are connected to the substrate 20. At this time, in the case where x y, when the length of each of the connection terminals 140 is small or the height of each of the heating components 4a to 4c is small, the distance between the cooling plate 6 and each connection terminal 140 is small. In this case, it is not possible to ensure a sufficient insulating distance between the cooling plate 6 and each connection terminal 140.

By contrast, in the case where the relationship x<y is satisfied, even when the length of the connection terminals 140 is small, a sufficient insulating distance is ensured between the cooling plate 6 and each connection terminal 140 at the time of attaching the heating components 4a to 4c to the cooling plate 6. Therefore, in Embodiment 3, the width x of the cooling plate 6 is reduced such that the relationship x<y is satisfied.

The heating component 4d is provided such that the widthwise direction of the heating component 4d is parallel to the flow direction of the refrigerant 11. That is, the heating component 4d is provided such that the longitudinal direction of the heating component 4d is perpendicular to the flow direction of the refrigerant 11. Therefore, as illustrated in FIG. 13, the connection terminals 140 of the heating component 4d are provided only on one side 4d-1 of the two long sides. The side 4d-1 is located on the upstream side in the flow direction of the refrigerant 11. That is, the side 4d-1 corresponds to a side 6b-1 of the protrusion portion 6b of the cooling plate 6 as illustrated in FIG. 11. As illustrated in FIG. 11, the side 6b-1 of the protrusion portion 6b is located inward of the side of the heating component 4d, on which the connection terminals 140 are provided. Thus, when the heating component 4d is attached to the cooling plate 6, it is possible to ensure a sufficient insulating distance between the cooling plate 6 and each connection terminal 140 even when the length of the connection terminals 140 is small. In order to obtain such an advantage, in Embodiment 3, the connection terminals 140 of the heating component 4d are provided on only one side of the heating component 4d that is located on the upstream side. As illustrated in FIG. 13, the side 4d-1 is opposite to a side 4d-2. The side 4d-2 corresponds to a side 6b-2 of the protrusion portion 6b of the cooling plate 6 as illustrated in FIG. 11. If connection terminals 140 were also provided at the side 4d-2 of the heating component 4d, it would not be possible to ensure a sufficient insulating distance between the cooling plate 6 and each of the connection terminals 140 without execution of processing, such as cutting, on the side 6b-2. However, in Embodiment 3, connection terminals 140 are not provided on the upstream side 4d-2 of the heating component 4d. As a result, regarding the side 6b-2 of the protrusion portion 6b, it is not necessary to consider whether an insulating distance is ensured for the connection terminal 140, and thus it is not necessary to perform processing, such as cutting, on the side 6b-2.

### Modification 2

FIG. 12 is a side view illustrating an internal configuration of the controller 5 of the air-conditioning apparatus according to Embodiment 3. In FIG. 12, illustration of the housing 5a of the controller 5 is omitted.

As illustrated in FIG. 12, metal plates 60 that serve as heat transfer members are provided between the cooling plate 6 and the heating components 4a to 4c. The metal plates 60 are each, for example, made of metal having a high thermal conductivity, such as copper. The metal plate 60 may be made of a material other than metal as long as the material has a high thermal conductivity.

By contrast, no metal plate 60 is provided between the heating component 4d and the cooling plate 6.

In such a manner, since the metal plates 60 are provided between the cooling plate 6 and the first heating components, which are intended to facilitate cooling, heat is transferred from the first heating components to the cooling plate 6 at a higher rate. Thus, cooling of the first heating components is further efficiently performed.

By contrast, no metal plate 60 is provided between the cooling plate 6 and the second heating component, which is intended to reduce cooling. Because of this configuration, it is possible to prevent excessive cooling of the second heating component, and thus reduce occurrence of condensation.

When the heating components 4a to 4d do not have the same height, this causes variations in the distances between the cooling plate 6 and the heating components 4a to 4c. In such a case, it is possible to compensate for the variations by changing the thickness of the metal plate 60 for each of the heating components 4a to 4c. In such a manner, the metal plate 60 has also a function of an adjustment member that causes the heating components 4a to 4c to be uniformly in contact with the cooling plate 6 by compensating for the distances between the heating components 4a to 4c and the cooling plate 6.

### Modification 3

FIG. 13 is a plan view illustrating an internal configuration of the controller 5 of the air-conditioning apparatus according to Embodiment 3. However, FIG. 13 illustrates the internal configuration except for the substrate 20. Therefore, in FIG. 13, illustration of the substrate 20, the control module 10, and the other components 19a to 19d are omitted. FIG. 13 illustrates the case where the cooling refrigerant pipe 14 has a return portion 14a.

In an example as illustrated in FIG. 13, the cooling refrigerant pipe 14 has a first portion 14b, a second portion 14c, and the return portion 14a. The first portion 14b corresponds to the cooling refrigerant pipe 14 which is provided as described regarding Embodiments 1 and 2, and its description will thus be omitted. In the example as illustrated in FIG. 13, the first portion 14b and the second portion 14c are accommodated in grooves 6c formed in the cooling plate 6.

As illustrated in FIG. 13, the second portion 14c is provided to extend parallel to the first portion 14b. The second portion 14c, as well as the first portion 14b, is attached to the cooling plate 6. The second portion 14c may be provided so as to extend through the inside of the cooling plate 6 or may be provided on the outer surface of the cooling plate 6. The second portion 14c is attached to the cooling plate 6 by brazing or other methods such that the second portion 14c is in direct contact with the cooling plate 6. The second portion 14c, as well as the first portion 14b, is, for example, made of metal having a high thermal conductivity, such as copper and aluminum. The second portion 14c may be attached to the cooling plate 6, with a seal member or other members interposed between the second portion 14c and the cooling plate 6; that is, the second portion 14c may be in indirect contact with the cooling plate 6. Because the second portion 14c is provided, the amount of heat radiated from the cooling plate 6 to the air is increased, thereby facilitating cooling. As a result, cooling of the heating components 4a to 4d is further facilitated.

As illustrated in FIG. 13, the return portion 14a of the cooling refrigerant pipe 14 is U-shaped as viewed in plan. The refrigerant 11 flows in the return portion 14a. The return portion 14a, as well as the first portion 14b, is, for example, made of metal having a high thermal conductivity, such as copper and aluminum. The first portion 14b and the second portion 14c of the cooling refrigerant pipe 14 are coupled by the return portion 14a, whereby the cooling refrigerant pipe 14 is provided as a single cooling refrigerant pipe. Therefore, as indicated by arrows in FIG. 13, the refrigerant 11 flows through the second portion 14c, the return portion 14a, and the first portion 14b in this order. Therefore, in the example as indicated in FIG. 13, of the heating components 4a to 4d, the heating component 4d is provided on the most upstream side in the flow direction of the refrigerant 11.

As described regarding Embodiment 1, the center position of the heating component 4d in the longitudinal direction thereof is offset in a direction indicated by the arrow C from the center position of the cooling refrigerant pipe 14 in the radial direction. At this time, as indicated by an arrow D, the direction in which the return portion 14a is returned is opposite to the direction indicated by the arrow C. That is, in the case where the heating component 4d is offset upward as viewed in a direction perpendicular to the plane of the drawing, the return portion 14a is returned downward as viewed in the direction perpendicular to the plane of the drawing.

In the case where the heating component 4d is offset upward as viewed in the direction perpendicular to the plane of the drawing, when the return portion 14a is also returned upward as viewed in the direction perpendicular to the plane of the drawing, the second portion 14c extends through a region close to the heating component 4d. Alternatively, as viewed in plan, the second portion 14c overlaps with the heating component 4d. In this case, a cooling effect of the heating component 4d is enhanced, and there is a possibility that the heating component 4d will be excessively cooled.

Therefore, the return portion 14a is returned in the opposite direction to the offset direction of the heating component 4d. As a result, it is possible to adequately cool the heating components 4a to 4d while reducing occurrence of condensation on the heating component 4d.

1. An air-conditioning apparatus comprising:
a refrigerant circuit in which a compressor, a condenser, an expansion valve, and an evaporator are connected by a refrigerant pipe through which refrigerant flows;
a bypass pipe through which part of the refrigerant discharged from a discharge port of the compressor flows; and
a controller configured to control an operation of the compressor,
wherein
both ends of the bypass pipe are connected to respective portions of the refrigerant pipe that are located between the condenser and a suction port of the compressor,
the controller includes
a substrate,
a control module configured to control the operation of the compressor,
a plurality of heating components provided on the substrate, and
a cooling plate that is provided between the bypass pipe and the plurality of heating components and configured to cool the plurality of heating components with the refrigerant flowing through the bypass pipe,
the plurality of heating components include
a first heating component, and
a second heating component configured to generate a smaller amount of heat than the first heating component,
the first heating component and the second heating component are provided in a region of the cooling plate that overlaps with the bypass pipe as the cooling plate is viewed in plan,
each of the first heating component and the second heating component has long sides and short sides as viewed in plan,
the first heating component is provided such that a longitudinal direction of the first heating component is parallel to a flow direction of the refrigerant in the bypass pipe, the longitudinal direction of the first heating component being a direction in which the long sides of the first heating component extends, and
the second heating component is provided such that a widthwise direction of the second heating component is parallel to the flow direction of the refrigerant in the bypass pipe, the widthwise direction of the second heating component being a direction in which the short sides of the second heating component extend.

2. The air-conditioning apparatus of claim 1, wherein
a plurality of first heating components identical to the first heating component are provided, and
the first heating components are arranged in a line such that short sides of the first heating components are opposite to each other as viewed in plan.

3. The air-conditioning apparatus of claim 1, wherein
the substrate has long sides and short sides as viewed in plan, and
the first heating component and the second heating component are provided side by side at central part of the substrate in a longitudinal direction thereof in which the long sides of the substrate extend.

4. The air-conditioning apparatus of claim 1, wherein the second heating component is provided such that a center position of the second heating component in the longitudinal direction is offset from a center position of the bypass pipe in a radial direction thereof as viewed in plan.

5. The air-conditioning apparatus of claim 1, wherein
the first heating component is an inverter module, and
the second heating component is a rectifier or a converter module.

6. The air-conditioning apparatus of claim 1, wherein
the cooling plate has a width and a length as viewed in plan, and
the width of the cooling plate is smaller than a length of each of the short sides of the first heating component.

7. The air-conditioning apparatus of claim 1, further comprising
a refrigerant flow control device configured to adjust an amount of the refrigerant flowing through the bypass pipe,
wherein
the control module is configured to control the operation of the compressor and an operation of the refrigerant flow control device, and
the control module includes temperature detectors configured to detect respective temperatures of the plurality of heating components, the controller being configured to control the operation of the refrigerant flow control device based on the temperatures detected by the temperature detectors.

8. The air-conditioning apparatus of claim 7, wherein the temperature detectors are internal thermistors each of which is provided in an associated one of the plurality of heating components or are temperature sensors each of which is attached to an associated one of the plurality of heating components.

9. The air-conditioning apparatus of claim 7, wherein
the control module has a first target temperature and a second target temperature lower than the first target temperature, and is configured to
determine a maximum temperature and a minimum temperature from the temperatures of the plurality of heating components that are detected by the temperature detectors,
determine an absolute value of a difference between the maximum temperature and the first target temperature as a first computation result value,
determine an absolute value of a difference between the minimum temperature and the second target temperature as a second computation result value,
cause the refrigerant flow control device to be in a closed state to stop a flow of the refrigerant in the bypass pipe, when the first computation result value is greater than or equal to the second computation result value, and
cause the refrigerant flow control device to be in an opened state to allow a flow of the refrigerant in the bypass pipe, when the first computation result value is less than the second computation result value.

10. The air-conditioning apparatus of claim 7, wherein
the control module has a first target temperature that is determined for the temperature of the first heating component, and a second target temperature that is determined for the temperature of the second heating component, and the control module is configured to
cause the refrigerant flow control device to be in an opened state to allow a flow of the refrigerant in the bypass pipe, when the temperature of the first heating component exceeds the first target temperature or the temperature of the second heating component exceeds the second target temperature, and
cause the refrigerant flow control device to be in a closed state to stop a flow of the refrigerant in the bypass pipe, when a condition in which the temperature of the first heating component exceeds the first target temperature or the temperature of the second heating component exceeds the second target temperature is not satisfied.

11. The air-conditioning apparatus of claim 7, wherein
the control module is configured to
determine in advance a threshold temperature range for the temperatures of the plurality of heating components, and
control opening and closing of the refrigerant flow control device such that the temperatures of the plurality of heating components fall within the threshold temperature range.

12. The air-conditioning apparatus of claim 11, wherein
an upper limit value of the threshold temperature range is determined based on heat resisting temperatures of the heating components, and
a lower limit value of the threshold temperature range is determined based on condensation temperatures of the heating components.

13. The air-conditioning apparatus of claim 1, wherein
the first heating component and the second heating component are electrically connected such that current flows from the second heating component toward the first heating component,
a flow direction of the refrigerant in the bypass pipe is parallel to a flow direction of the current, and
in the flow direction of the refrigerant in the bypass pipe, the second heating component is provided upstream of the first heating component.

14. The air-conditioning apparatus of claim 13, wherein the first heating component and the second heating component are provided on the substrate in an order in which the first heating component and the second heating component are electrically connected.

15. The air-conditioning apparatus of claim 13, wherein
the second heating component is provided such that a longitudinal direction in which the long sides of the second heating component extend is perpendicular to the flow direction of the refrigerant in the bypass pipe, and
a connection terminal of the second heating component is provided at an upstream one of the long sides of the second heating component.
